(19) United States
(12) Patent Application Publication
(10) Pub. No.: US 2026/0150245 A1
(43) Pub. Date: May 28, 2026

(54) THERMAL MANAGEMENT FOR CIRCUIT COMPONENTS

(71) Applicant: Mellanox Technologies, Ltd., Yokneam (IL)

(72) Inventors: John Franz, Tomball, TX (US); Tahir Cader, Spokane Valley, WA (US); Elad Mentovich, Tel Aviv (IL); Boaz Atias, Ma'ale Adumim (IL)

(21) Appl. No.: 18/960,687

(22) Filed: Nov. 26, 2024

(51) Int. Cl. H05K 7/20

(52) U.S. Cl. CPC H05K 7/2039; H05K 7/20709

(57) ABSTRACT

A system includes one or more computing components disposed on a first side of a circuit board within a server chassis. The system further includes a cooling device disposed at least partially on a second side of the circuit board opposite the first side of the circuit board. The system further includes a heat-conducting component configured to transport heat away from a first computing component of the one or more computing components to the cooling device. The heat-conducting component includes a main body coupled to the one or more computing components. The main body is approximately parallel to the circuit board. The heat-conducting component further includes a heat-dissipation feature extending from the main body. The heat-dissipation feature extends from the first side of the circuit board to the second side of the circuit board and is coupled with the cooling device.

### TECHNICAL FIELD

At least one embodiment pertains to cooling for one or more circuit components. For example, at least one embodiment pertains to a system for cooling a circuit component.

### BACKGROUND

Circuit components such as CPUs, DPUs, and GPUs are often cooled by air cooling and/or by liquid cooling. Some circuit components are disposed on a top side of a circuit board while other circuit components are disposed on a bottom side of the circuit board. Cooling of the bottom side components can be challenging because of lack of space within a circuit chassis for cooling lines, etc.

### BRIEF DESCRIPTION OF DRAWINGS

Various embodiments in accordance with the present disclosure will be described with reference to the drawings, in which:

FIG. 1 is a simplified cutaway schematic view of a system cooled using a heat-conducting component, in accordance with at least some embodiments.

FIG. 2A illustrates a simplified side schematic view of an example heat-conducting component, thermal interface, and cooling device, in accordance with at least some embodiments.

FIG. 2B illustrates a simplified perspective view of an example heat-conducting component, in accordance with at least some embodiments.

FIGS. 3A-3D illustrate simplified views of an example thermal interface, in accordance with at least some embodiments.

FIGS. 4A-4B illustrate simplified cutaway perspective views of an example computing circuit cooled using a heat-conducting component, in accordance with at least some embodiments.

FIG. 5 is a flow diagram of an example method of assembling and using a heat-conducting component to cool a computing component, in accordance with at least some embodiments.

FIGS. 6A-6B illustrate a network architecture, in accordance with at least some embodiments.

FIG. 7 illustrates a distributed system, in accordance with at least some embodiments.

FIG. 8 illustrates an exemplary data center, in accordance with at least some embodiments.

FIG. 9 illustrates a client-server network, in accordance with at least some embodiments.

FIG. 10 illustrates a computer network, in accordance with at least some embodiments.

FIG. 11A illustrates a networked computer system, in accordance with at least some embodiments.

FIG. 11B illustrates a networked computer system, in accordance with at least some embodiments.

FIG. 11C illustrates a networked computer system, in accordance with at least some embodiments.

FIG. 12 illustrates an example datacenter cooling system, according to at least some embodiments.

FIG. 13 illustrates a schematic diagram of a datacenter cooling system, according to at least some embodiments.

### DETAILED DESCRIPTION

High performance computing circuits often include powerful computing components such as processing devices (e.g., that may include graphical processing units (GPUs), central processing units (CPUs), data processing units (DPUs), memory, etc.). Such high-performance computing components are regularly implemented on a printed circuit board (PCB) having many other computing components and/or other circuit components. Because of the increasing density of components in computing devices (e.g., in a server chassis), components are now often coupled to the PCB on a top side of the PCB and a bottom side (back side) of the PCB. Many components included in computing circuits output heat. Cooling measures and infrastructure are included in a server chassis to cool the computing components. Some computing components are coupled to a top side of a PCB and can be easily cooled by air cooling (e.g., by flowing air through the server chassis) and/or by liquid cooling (e.g., by flowing liquid coolant through cold plates thermally coupled with the computing component(s)). However, some computing components are coupled to a bottom side of the PCB away from direct access to cooling liquid. The computing components on the bottom side of the PCB often cannot be as easily cooled because of the lack of space between the bottom of the PCB and the bottom of the server chassis. In some embodiments, there is limited space between the bottom-side computing components (e.g., computing components on the bottom side of the PCB) and the bottom of the server chassis. Because of the limited space, conventional cooling solutions like air cooling and/or liquid cooling using cold plates may be ineffective or difficult to implement.

Some existing cooling solutions transfer heat from the bottom side of the circuit board to the top side of the circuit board using solid copper blocks. However, these solid copper blocks provide limited thermal performance. For example, the thermal performance may be limited both in heat capacity and distance. In some of the existing solutions, the connection between the top side and the bottom side of the circuit board is a small, flat area parallel with the PCB. Additionally, the connections used for existing solutions use interface pads that are only capable of a single use (e.g., the pads are replaced if the interface is ever disassembled). Because of the low thermal performance of the existing solutions, only low-power computing components that are placed on a bottom side of a PCB can be effectively cooled. This limits the ability to place higher power computing components on the bottom side of a PCB. However, in some embodiments, it can be beneficial to place high-power computing components on the bottom side of a PCB. Conventional cooling solutions that are available for cooling components on a bottom side of a PCB do not have sufficient thermal capability for effectively cooling high-power components such as GPUs, CPUs, DPUs, etc.

Aspects of the present disclosure address the deficiencies described above and other challenges by providing improved cooling components on a bottom of a PCB that can effectively cool high power computing components placed on the bottom of the PCB. The cooling components may include a heat-conducting component to transport heat from the bottom side of the PCB to the top side of the PCB. In some embodiments, the heat-conducting component conducts heat horizontally away from the high-power computing device toward a sidewall of a server chassis. In some embodiments, the heat-conducting component includes a thin main body (e.g. ultra thin) which can fit in the space between the bottom side computing components and the bottom of a chassis (e.g., a server chassis, etc.) creating a complete thermal path. The main body of the heat-conducting component may be highly thermally conductive for transferring high heat loads over long distances. For example, and in some embodiments, heat loads can be transferred over distances between approximately 50 mm and approximately 250 mm. In some embodiments, the heat-conducting component includes a heat-dissipation feature (e.g., a protrusion, a vertical wall, etc.) which protrudes from the main body. The heat-dissipation feature may extend from the bottom side of the PCB to the top side of the PCB. The heat-dissipation feature may be included for increasing the surface area of contact between the cooling components on the bottom side of the PCB with a cooling device on a top side of the PCB for heat dissipation. In some embodiments, because of the high density of components (e.g., circuitry, cooling lines, circuit connections, component components, etc.) near the middle of a PCB and/or within a server chassis, the heat-dissipation feature may be disposed proximate to the periphery of the server chassis. In some embodiments, the heat-dissipation feature is disposed adjacent to a sidewall of the server chassis.

A cooling device may be coupled to the heat-conducting component by the heat-dissipation feature. In some embodiments, the cooling device receives liquid coolant and transfers the heat from the heat-conducting component to the liquid coolant. In some embodiments, a thermal interface is included between the cooling device and the heat-dissipation feature. The thermal interface may enhance the heat transfer of heat between the heat-dissipation feature and the cooling device. The thermal interface may include a thermal interface pad and/or a copper layer. The thermal interface may be reusable for a plurality of mating cycles (e.g., may be reusable for assembly/reassembly of the heat-dissipation feature to cooling device connection, etc.). In some embodiments, the thermal interface can be repeatedly assembled/disassembled without damage such as during multiple different service/maintenance events. In some embodiments, heat flows from the computing component(s) to the cooling device via the heat-conducting component. The main body of the heat-conducting component may be coupled with the computing component. Heat may be transferred from the computing component to the main body of the heat-conducting component. The heat may be transported through the main body to the heat-dissipation feature. The transported heat may then be dissipated to the cooling device via the thermal interface between the heat-dissipation feature and the cooling device. The heat may be transferred to liquid coolant in the cooling device and transported away (e.g., such as to a heat exchanger, etc.).

Advantages of the present disclosure include, but are not limited to, for example, improved cooling for computing components disposed on a bottom side of a PCB in a server chassis (e.g., in a computing circuit chassis, etc.). By improving the cooling for bottom side computing components, component integrity and performance can be maintained. In some examples, the present disclosure provides a high heat transfer rate while minimizing the space used, such as for cooling bottom-side computing components, and without posing an additional leak risk (e.g., cooling fluid leak risk, etc.). The devices and systems described herein can use minimal space within a server chassis. The space within the server chassis can thus be conserved such as for the inclusion of more computing components and/or other features to support computing components, etc. Further, the present disclosure provides a heat transfer system that can be repeatedly be assembled and disassembled multiple times without damage, unlike at least some prior solutions. Moreover, implementations of the present disclosure provide a more cost-effective and/or simpler approach to solving the above-described problem than other possible solutions which can lead to lower cost and reduced power consumption.

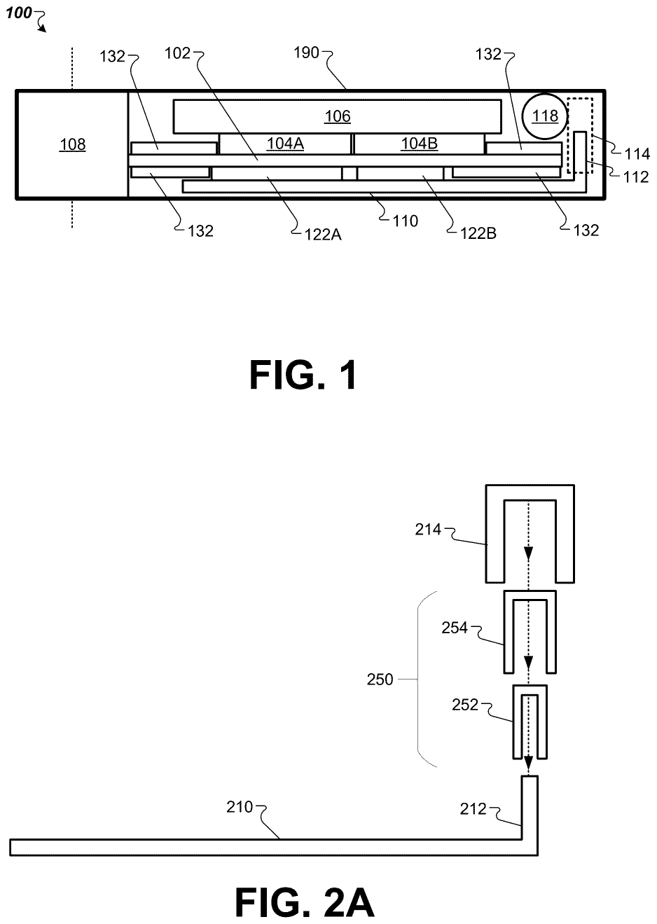

FIG. 1 is a simplified cutaway schematic view of a system 100 that includes one or more high power computing components 122A-B disposed on a first side (e.g., bottom side) of a circuit board within a server chassis and cooled using a heat-conducting component 110, in accordance with at least some embodiments. In some embodiments, only half of computing circuit 100 is shown (e.g., a right half). A second half (e.g., a left half) of the computing circuit 100 may include substantially the same components as those illustrated in some embodiments. Computing circuit 100 may represent a server, such as a rackmount server in a datacenter, etc.

In some embodiments, computing circuit 100 is disposed within a chassis 190. Chassis 190 may be a server chassis that includes a sheet metal container having sidewalls, a bottom, and a top. Chassis 190 may contain a system PCB 102. A PCB is used to electrically connect electronic components using conductive pathways, or traces, etched from metal sheets. In many electronic systems, one or more very large-scale integrated circuit (“VLSI”) components is coupled to a host system printed circuit board (“PCB”). Such VLSI components may include, for example, central processing unit (“CPU) devices and graphics processing unit (“GPU”) devices. The PCB may hold at least one processing circuitry. The processing circuitry may comprise hardware, such as an application specific integrated circuit (ASIC). The processing circuitry may comprise an ASIC and/or may be capable of performing as a central processing unit (CPU), a graphics processing unit (GPU), a network interface card (NIC), a data processing unit (DPU), or any other computing device in which with data is received and/or transmitted. Other non-limiting examples of the processing circuitry include an Integrated Circuit (IC) chip, a Central Processing Unit (CPU), a Graphics Processing Unit (GPU), a microprocessor, a Field Programmable Gate Array (FPGA), a collection of logic gates or transistors, resistors, capacitors, inductors, diodes, or the like. It should be appreciated that any appropriate type of electrical or optical component or collection of electrical or optical components may be suitable for inclusion in the processing circuitry.

Numerous example embodiments will be described below in which a semiconductor package is mounted within a through hole of a PCB. Although PCBs having certain types and form factors appear in the drawings and the discussion, it should be noted that the illustrated and described types and form factors are provided by way of example only. Persons having skill in the art and having reference to this disclosure will readily appreciate that the same or similar apparatus and techniques may also be employed with PCBs having other types and form factors. For example, in some embodiments, the PCB to which the semiconductor package is mounted may comprise an add-in card, such as a PCIe card, that is configured to be coupled to a system board or motherboard of a host system. In other embodiments, the PCB to which the semiconductor package is mounted may be the system board or motherboard of the host system itself. Moreover, the system board or the motherboard may be associated with any type of host system. For example, the PCB may comprise the system board in a multi-node rack-mounted server in a data center, or it may comprise the motherboard of a workstation, desktop, laptop, or mobile device. Other embodiments are also possible.

PCB 102 may be referred to as a printed circuit assembly (PCA). PCB 102 may include multiple computing components 104A, 104B, 122A, 122B mounted thereto. The multiple computing components 104A-B, 122A-B may include high power computing components and/or lower power computing components. Examples of high power computing components include a GPU, DPU, CPU, integrated voltage regulators, electrical and optical devices, memory, and so on. Examples of low power computing components include a motherboard, memory, a network interface card (NIC), a solid state drive or hard drive, an audio card, and so on. In some embodiments, low-power components output less than a threshold amount of heat and high-power components output more than the threshold amount of heat.

Chassis 190 may include power connectors and bus bars 108 disposed therein, which may provide connections (e.g., power connections, data connections, etc.) to computing components 104A-B, 122A-B coupled to the PCB 102. In some embodiments, multiple computing components are coupled with the PCB 102. Some computing components 104A-B may be coupled on a second top side of the PCB 102 and other computing components 122A-B may be coupled on a bottom side of the PCB 102. For example, and in some embodiments, computing component 144A may be a first GPU and computing component 144B may be a second GPU, each of which may be coupled on a top side of PCB 102. In another example, and in some embodiments, one or more computing components 122A-B (e.g., which may be high power computing components) may be coupled on a bottom side of PCB 102. One or more stiffeners 132 may be coupled to the PCB 102 to provide stiffening structure thereto. The stiffeners 132 may be coupled to the top and/or to the bottom of PCB 102 in embodiments.

In some embodiments, computing components 104A-B coupled on a top side of PCB 102 may be cooled using conventional liquid, two-phase, and/or air cooling. For example, computing components 104A-B may be cooled by a cold plate 106 (or respective cold plates) that is coupled with the tops of the computing components 104A-B. The cold plate 106 may receive a liquid coolant or a two-phase coolant in embodiments. Heat from the computing components 104A-B may be provided to the coolant via the cold plate 106. The coolant may carry the heat out of the chassis 190 to a heat exchanger where the coolant may be refreshed (e.g., cooled) and recirculated. In some embodiments, there is sufficient room between the tops of the top side computing components (e.g., computing components 104A-B coupled on the top of the PCB 102) and the top of chassis 190 for the conventional cooling using cold plates, fans, etc. as described above.

In some embodiments, computing components 122A-B coupled on a bottom side of PCB 102 may be cooled using a heat-conducting component 110 as described herein. In some embodiments, the heat-conducting component 110 is configured to transport heat from the bottom side computing components 122A-B on the bottom side of the PCB 102 to the top side of the PCB 102. For example, and in some embodiments, the heat-conducting component 110 may transport heat to the edge of the chassis 190 and upwards from the bottom side of the PCB 102 to the top side of the PCB 102. In some embodiments, the heat-conducting component 110 transports heat through a gap formed in the PCB 102 and/or through a gap formed between an edge of the PCB 102 and a side wall of the chassis 190 to the cooling device 114. In some embodiments, the heat-conducting component 110 may be integrated into the bottom wall of the chassis 190. For example, the heat-conducting component 110 may form at least a portion of the server chassis 190, providing a structural element for the chassis 190 while conducting heat from the computing components 122A-B.

In some embodiments, the heat-conducting component 110 is or includes a vapor chamber. For example, and in some embodiments, the heat-conducting component 110 forms internal channels through which vapor and/or liquid may travel to transport heat from the bottom side computing component(s) 122A-B. The internal channels may enable a closed-loop fluid cycle to transport heat away from the bottom side computing devices 122 to the cooling device 114. A closed-loop fluid cycle may include a loop of flowing fluid where the fluid in liquid form receives heat and evaporates to a vapor form. The fluid in vapor form may flow to a heat dissipation region of the loop and dissipate heat. The fluid may condense as heat dissipates and the fluid may flow in liquid form to receive more heat. The fluid may flow continuously without interruption in a cyclic manner.

In some embodiments, the heat-conducting component 110 is or includes a solid body of heat-conducting material providing a super high conducting structure. For example, and in some embodiments, the heat-conducting component 110 is made of a solid body of copper, aluminum, graphene, and/or silver diamond.

The heat-conducting component 110 may have a high thermal conductivity. In some embodiments, the heat-conducting component 110 has a thermal conductivity between approximately 300 W/(m*K) and approximately 5,000 W/(m*K). In some embodiments, the heat-conducting component 110 has a thermal conductivity between approximately 500 W/(m*K) and approximately 3,000 W/(m*K). In some embodiments, the heat-conducting component 110 has a thermal conductivity above approximately 1,000 W/(m*K).

In some embodiments, the heat-conducting component 110 includes a main body coupled with the one or more computing components 122A-B on the bottom side of PCB 102 fitting a very thin are under the PCB 102. In some embodiments, the main body is approximately parallel to the circuit board. The main body of the heat-conducting component may be disposed substantially between the bottom side computing components 122A-B and the bottom of the chassis 190. In some embodiments, the main body of the heat-conducting component 110 has a thickness between approximately one millimeter and approximately seven millimeters. In some embodiments, the main body of the heat-conducting component 110 has a thickness between approximately three millimeters and approximately five millimeters. The space between the bottoms of the bottom side computing component(s) 122A-B and the bottom of the chassis 190 may be wider than the thickness of the heat-conducting component 110. For example, and in some embodiments, the space between the bottoms of the bottom side computing components 122A-B and the bottom of the chassis 190 may be between approximately two millimeters and approximately eight millimeters. In some embodiments, the space between the bottoms of the bottom side computing components 122A-B and the bottom of the chassis 190 may be between approximately four millimeters and approximately six millimeters.

Heat from the bottom side computing component(s) 122A-B may be transported for long distances i.e. through the main body of the heat-conducting component 110 to a heat-dissipation feature 112 of the heat-conducting component 110. In some embodiments, the heat-dissipation feature 112 is a protrusion protruding from the main body of the heat-conducting component. In some embodiments, the heat-dissipation feature 112 is substantially orthogonal to the main body. For example, the heat-dissipation feature 112 may be a vertical wall. The heat-dissipation feature 112 may be an integrated feature of the main body or may be coupled with the main body. In some embodiments, the heat-dissipation feature 112 extends from the main body near the periphery of the heat-conducting component 110 and extends from the first side of the circuit board to the second side of the circuit board and is coupled with the cooling device 114. For example, the heat-dissipation feature 112 may protrude near an edge of the heat-conducting component 110. In other embodiments, the heat-dissipation feature 112 extends from the main body away from the periphery of the heat-conducting component 110. For example, the heat-dissipation feature may protrude near the center (e.g., away from the edges) of the heat-conducting component 110.

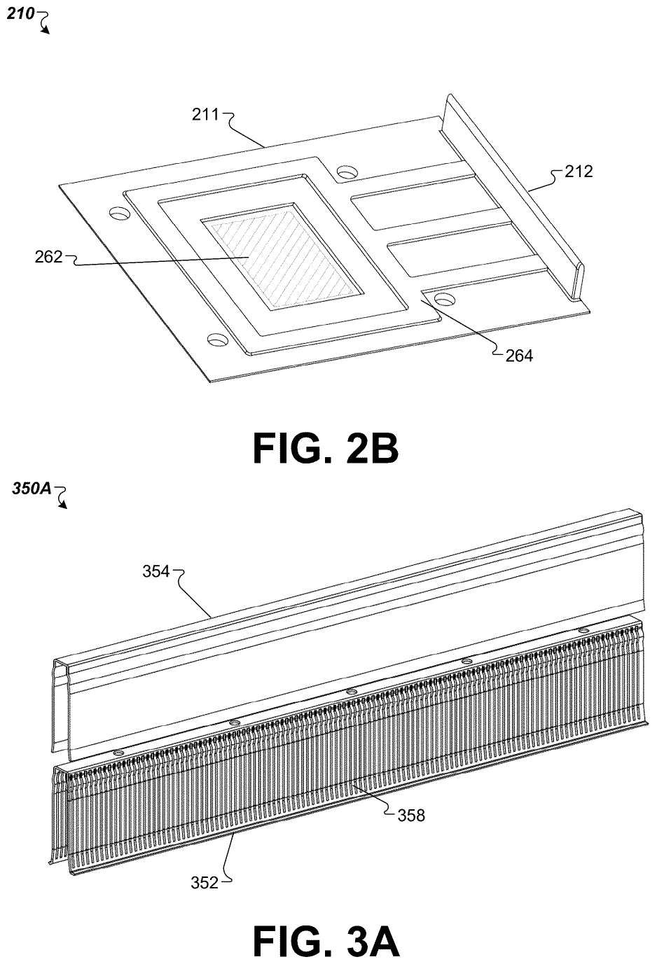

In some embodiments, heat from the bottom side computing component(s) 122A-B is provided from the heat-dissipation feature 112 to a cooling device 114. The cooling device 114 may be disposed at least partially on a second side of the circuit board opposite the first side of the circuit board adjacent to a side wall of the chassis 190. Cooling device 114 may be a liquid cooling device or a two-phase fluid cooling device. In some embodiments, cooling device 114 receives coolant (e.g., liquid coolant and/or two-phase coolant) from a coolant line 118. Coolant line 118 may be a coolant hose or a coolant pipe, etc. Heat from the heat-dissipation feature 112 may be provided to the coolant via the cooling device 114. In some embodiments, a reusable thermal interface is disposed between the heat-dissipation feature 112 and the cooling device 114. More details regarding the thermal interface are described herein with respect to FIG. 2A.

FIG. 2A illustrates a simplified side schematic view of an example heat-conducting component 210, thermal interface 250 being attached to a cooling device 214, in accordance with at least some embodiments. Heat-conducting component 210 may correspond to heat-conducting component 110 described herein above with respect to FIG. 1. Similarly, cooling device 214 may correspond to cooling device 114 described herein above with respect to FIG. 1.

In some embodiments, heat-dissipation feature 212 extends orthogonally from the main body of the heat-conducting component 210. Heat transported by the heat-conducting component 210 may be dissipated to the cooling device 214 via the thermal interface 250. In some embodiments, the thermal interface 250 mates with the heat-dissipation feature 212 and/or with the cooling device 214. The thermal interface 250 may form an interface for providing heat from one or more outer surfaces of the heat-dissipation feature 212 to one or more inner surfaces of the cooling device 214. In some embodiments, thermal interface 250 is a reusable interface. For example, during disassembly of the heat-conducting component 210 from the cooling device 214, the thermal interface 250 may be disassembled. During reassembly, however, the thermal interface 250 may be reused. In some embodiments, the thermal interface 250 is reusable for a plurality of mating cycles (e.g., a plurality of assembly/disassembly cycles, etc.).

In some embodiments, the thermal interface 250 includes a thermal interface pad 254 disposed between the heat-dissipation feature 212 (e.g., the outer surface(s) of the heat-dissipation feature 212, etc.) and the cooling device 214 (e.g., the inner surface(s) of the cooling device 214). Thermal interface pad 254 may be configured as a hybrid gap pad with thin compliant metal springs to protect the pad from sliding damage from multiple insertion cycles. In some embodiments, the thermal interface pad 254 is a silicon thermal gap pad. The thermal interface pad 254 may have a rubbery springiness such that the thermal interface pad 254 can be squeezed into the space between the cooling device 214 and the heat-dissipation feature 212. This rubbery springiness enables the thermal interface pad 254 to fit to surfaces having different dimensions. In some embodiments, the thermal interface pad 254 has a tacky outer surface so that the thermal interface pad 254 may stick to one or more surfaces. In some embodiments, the thermal interface pad 254 has a thickness between approximately 1.5 millimeters and approximately 2 millimeters. In some embodiments, the thermal interface pad 254 has a thickness between approximately 0.5 millimeters and 0.8 millimeters. In some embodiments, the thermal interface pad 254 has a thickness between approximately 1.0 millimeters and approximately 1.5 millimeters.

In some embodiments, the thermal interface 250 includes a copper layer 252 disposed on the thermal interface pad 254. The copper layer 252 may be disposed between the thermal interface pad 254 and the outer surface(s) of the heat-dissipation feature 212. In some embodiments, the copper layer 252 has a thickness between approximately 0.15 millimeters and approximately 0.20 millimeters. In some embodiments, the copper layer 252 has a thickness equivalent to approximately one tenth the thickness of the thermal interface pad 254. In some embodiments, the copper layer 252 provides a protective buffer between the thermal interface pad 254 and the heat-dissipation feature 212. The copper layer 252 may be included so that the thermal interface pad 254 can be removed and/or replaced on the heat-dissipation feature 212 without damage to the thermal interface pad 254.

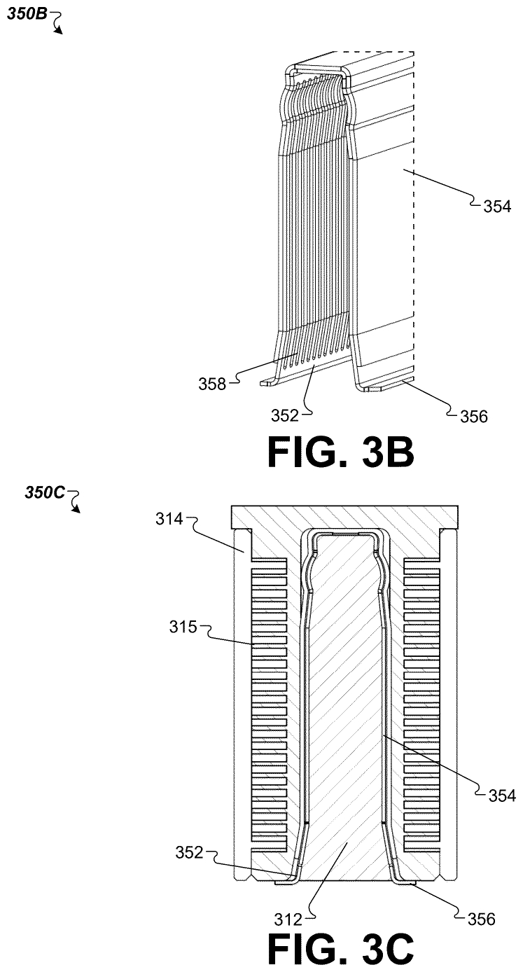

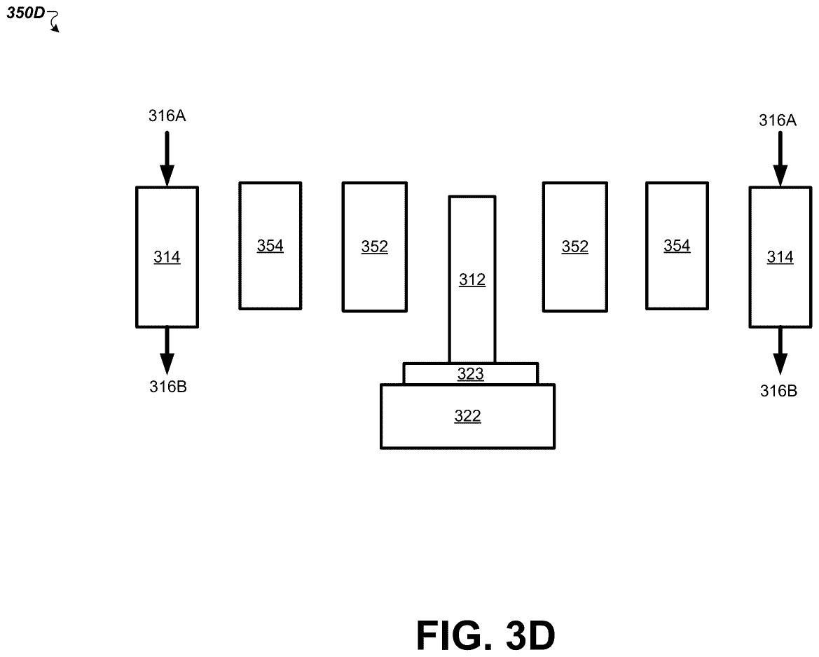

In some embodiments, the thermal interface pad 254 is wrapped on top of the copper layer 252 between the copper layer 252 and an inner surface of the cooling device 214. The thermal interface pad 254 and the copper layer 252 may form a compression fit within the cooling device 214. In this way, the thermal interface pad 254 may provide tolerance and compression fit to generate a normal force to overcome contact resistance. For example, when mating (e.g., such as during assembly and service, etc.) the heat-dissipation feature 212 with the cooling device 214 (e.g., such as during assembly, etc.), the thermal interface 250 may be squeezed into an opening formed within the cooling device 214. In some embodiments, the copper layer 252 forms a plurality of slits (e.g., a plurality of vertical slits). The thermal interface pad 254 may at least partially squeeze into the slits responsive to a compressive force exerted on the thermal interface pad 254 responsive to insertion of the heat-dissipation feature 212 into the thermal interface 250 (e.g., installation of the thermal interface 250 onto the heat-dissipation feature 212). More details regarding the plurality of slits formed in the copper layer 252 are discussed herein below with respect to FIGS. 3A-3C. The slits in the copper layer 252 may make the copper layer 252 more flexible to allow surfaces (e.g., of the thermal interface pad 254 and/or of the copper layer 252, etc.) to conform for optimal thermal performance. The slits may also provide a space for the gap pad to “flow” and deform into.

FIG. 2B illustrates a simplified perspective view of an example heat-conducting component 210, in accordance with at least some embodiments. In some embodiments, heat-conducting component 210 is a vapor chamber or a solid body of heat-conducting material (e.g., graphene, silver diamond, etc.). In some embodiments, the main body 211 of the heat-conducting component 210 is configured to couple to one or more bottom side computing components (e.g., a computing component on a bottom side of a PCB). One or more computing components may be disposed within one or more wells (e.g., well 262) formed in the main body 211. In some embodiments, a thermal interface pad is disposed between the one or more computing components and the surface of the main body 211. In embodiments where the heat-conducting component 210 is a vapor chamber, the outer surfaces of the heat-conducting component 210 may be made up of copper. In some embodiments, one or more channels 264 are formed in the main body 211. The channels 264 may be widened portions for the flow of vapor and/or liquid coolant within the main body 211. In some embodiments, the channels 264 at least partially form a closed-loop circuit for the flow of vapor and/or liquid coolant within the main body 211.

In some embodiments (e.g., such as when heat-conducting component 210 is a vapor chamber), a wick structure may be disposed within the main body 211. The wick structure may be disposed within the channels 264. The wick structure may aid in the transport of vapor and/or liquid within the main body 211 to and/or from the heat-dissipation feature 212. Liquid within the main body 211 and proximate the well 262 (and therefore proximate to a heat-producing computing component, etc.) may evaporate to produce a vapor. The vapor may travel to the heat-dissipation feature 212, carrying the heat away from the well 262. In some embodiments, the heat-dissipation feature 212 forms a hollow cavity serving as a condenser. Heat carried in the vapor may dissipate through the surface(s) of the heat-dissipation feature 212 (e.g., such as to a cooling device 214). The vapor may cool as heat is dissipated and may condense into a liquid. The condensed liquid may travel back toward the well 262. The wick structure within the main body 211 may aid in transporting the liquid back toward the well 262 from the heat-dissipation feature 212.

In some embodiments, the heat-dissipation feature 212 increases the surface area of the heat-conducting component 210 that can be used for dissipating heat. Without the heat-dissipation feature 212, the surface area of the heat-conducting component 210 that can be used for dissipating heat may be roughly equivalent to the size of the footprint of the heat-dissipation feature 212 on the main body 211. The footprint of the heat-dissipation feature 212 on the main body 211 may correspond to the two-dimensional area of the heat-dissipation feature 212 projected on the main body 211. In some embodiments, the surface area of the heat-dissipation feature 212 is between approximately five times (5×) and approximately ten times (10×) greater than the footprint of the heat-dissipation feature 212. In some embodiments, the heat-dissipation feature 212 increases a surface area of the heat-conducting component 210 for dissipating heat by between approximately 5× and approximately 10× of a surface area that the heat-conducting component for dissipating heat absent the heat-dissipation feature 212. For example, the heat-conducting component 210 having the heat-dissipation feature 212 has between 5× and 10× more surface area for dissipating heat than a heat-conducting component 210 lacking the heat-dissipation feature 212. In some embodiments, the heat-dissipation feature 212 has a thickness between approximately one millimeter and approximately seven millimeters. In some embodiments, the heat-dissipation feature 212 has a thickness between approximately two millimeters and approximately five millimeters. In some embodiments, the heat-dissipation feature 212 has a thickness of approximately three millimeters. In some embodiments, the heat-dissipation feature 212 is to fit between an edge of a PCB and a side wall of a server chassis.

FIGS. 3A-3D illustrate simplified views of an example thermal interface 350A-350D, in accordance with at least some embodiments. Thermal interface 350A-350D may correspond to thermal interface 250 of FIG. 2A.

Referring to FIG. 3A, components of a thermal interface 350A are shown. A thermal interface pad 354 and a copper sheet 352 may be included in the thermal interface 350A. The copper sheet 352 may form a plurality of slits 358. The slits 358 may be oriented vertically The thermal interface pad 354 may at least partially squeeze into the slits 358 responsive to a compressive force exerted on the thermal interface pad 354 The slits in the copper layer 352 may make the copper layer 352 more flexible to allow surfaces (e.g., of the thermal interface pad 354 and/or of the copper layer 352, etc.) to conform for optimal thermal performance. The slits 358 may also provide a space for the gap pad to “flow” and deform into.

Referring to FIG. 3B, an at least partially assembled thermal interface 350B is shown. In some embodiments, the thermal interface pad 354 substantially wraps over the outside surface(s) of a copper sheet 352. A heat-dissipation feature (e.g., heat-dissipation feature 312 shown in FIG. 3C) of a heat-conducing component described herein can be inserted into the open space within the copper sheet 352. When compressed (such as when the thermal interface 350 is installed into a cooling device, etc.), the thermal interface pad 354 may at least partially squeeze into the slits 358. For example, and in some embodiments, responsive to a compressive force exerted on the thermal interface pad 354 for insertion of the heat-dissipation feature 312 within the opening formed by the copper sheet 352, the thermal interface pad 354 may at least partially squeeze into the slits 358.

In some embodiments, the thermal interface 350 is reusable. For example, the thermal interface 350 can be used and reused such as for a plurality of assembly/reassembly cycles to a heat-dissipation feature and/or a cooling device. In some embodiments, the copper sheet 352 protects the thermal interface pad 354 from sliding of the heat-dissipation feature into the opening formed by the copper sheet 352 (e.g., such as during assembly or disassembly, etc.). In some embodiments, the copper sheet 352 forms flanges 356 to protect the edges of the pad 354. The copper sheet may be made from copper, but can alternatively be made from another suitable material such as aluminum, etc.

Referring to FIG. 3C, an assembled thermal interface 350C is shown. In some embodiments, a heat dissipation feature 312 of a heat-conducting component described herein is inserted into the open space within the copper sheet 352. Heat from the heat-dissipation feature 312 may be provided to a cooling device 314 via the copper sheet 352 and the thermal interface pad 354. In some embodiments, the cooling device 314 includes fins 315. Cooling fluid (e.g., liquid cooling fluid, gaseous cooling fluid, two-phase cooling fluid, etc.) may flow between the fins 315 for dissipation of the heat to the cooling fluid. As shown, the flanges 356 may protect the edges of the thermal interface pad 354, such as during assembly of the thermal interface 350C to the heat-dissipation feature 312 and/or to the cooling device 314.

Referring to FIG. 3D, a simplified cross-section of a thermal interface 350D is shown. Although the components of thermal interface 350D are illustrated with a gap between adjacent components, in some embodiments, each adjacent component of thermal interface 350D are touching one another so that heat conduction between components can occur.

In some embodiments, a computing component 322 generates heat that is to be provided to cooling fluid flowing through the cooling device 314 via the thermal interface 350D. The computing component 322 may be a bottom-side computing component (e.g., on a bottom-side of a PCB, etc.) as described herein. In some embodiments, th computing component 322 generates between approximately 200 Watts and approximately 600 Watts of heat. In some embodiments, the computing component 322 generates approximately 400 Watts of heat. The heat generated by the computing component 322 may be transferred to a heat-conducting component having a heat-dissipation feature 312 via a thermal interface pad 323. In some embodiments, the interface between the computing component 322 and the pad 323 has a temperature between approximately 84 degrees Celsius and approximately 92 degrees Celsius. In some embodiments, the interface between the computing component 322 and the pad 323 has a temperature of approximately 88 degrees Celsius. In some embodiments, the pad 323 has a thermal conductivity value between approximately 5 Watts per meter-Kelvin (W/mK) and approximately 9 W/mK). In some embodiments, the pad 323 has a thermal conductivity value of approximately 7 W/mK. In some embodiments, the pad 323 is between approximately 0.05 mm and approximately 0.1 mm thick. In some embodiments, the interface between the pad 323 and the heat-conducting component having a heat-dissipation feature 312 has a temperature between approximately 80 degrees Celsius and approximately 88 degrees Celsius. In some embodiments, the interface between the pad 323 and the heat-conducting component having a heat-dissipation feature 312 has a temperature of approximately 84 degrees Celsius.

Heat from the computing component 322 may be dissipated by the heat-dissipation feature 312 to the cooling device 314 by the copper sheet 352 and/or the thermal interface pad 354. In some embodiments, the interface between the heat-dissipation feature 312 and the copper sheet 352 has a temperature between approximately 68.5 degrees Celsius and approximately 76.5 degrees Celsius. In some embodiments, the interface between the heat-dissipation feature 312 and the copper sheet 352 has a temperature of approximately 75.2 degrees Celsius. In some embodiments, the copper sheet 352 has a thermal conductivity value between approximately 150 W/mK and approximately 250 W/mK. In some embodiments, the copper sheet 352 has a thermal conductivity value of approximately 200 W/mK. In some embodiments, the copper sheet 352 has a thickness between approximately 0.1 mm and approximately 0.3 mm. In some embodiments, the copper sheet 352 has a thickness of approximately 0.2 mm. In some embodiments, the interface between the copper sheet 352 and the thermal interface pad 354 has a temperature between approximately 67 degrees Celsius and approximately 75 degrees Celsius. In some embodiments, the interface between the copper sheet 352 and the thermal interface pad 354 has a temperature of approximately 71 degrees Celsius. In some embodiments, the thermal interface pad 354 has a thermal conductivity value between approximately 5 W/mK and approximately 10 W/mK. In some embodiments, the thermal interface pad 354 has a thermal conductivity value of approximately 7.5 W/mK. In some embodiments, the thermal interface pad has a thickness between approximately 0.1 mm and approximately 0.3 mm. In some embodiments, the thermal interface pad 354 has a thickness of approximately 0.2 mm.

Heat may be provided via the copper sheet 352 and/or the thermal interface pad 354 to the cooling device 314. In some embodiments, the interface between the thermal interface pad 354 and the cooling device 314 has a temperature between approximately 56 degrees Celsius and approximately 64 degrees Celsius. In some embodiments, the interface between the thermal interface pad 354 and the cooling device 314 has a temperature of approximately 60 degrees Celsius. In some embodiments, the heat is provided to a cooling fluid flowing through the cooling device 314. Cooling fluid 316A may be provided to the cooling device 314. In some embodiments, the cooling fluid 316A is provided to the cooling device 314 at a temperature between approximately 46 degrees Celsius and approximately 54 degrees Celsius. In some embodiments, the cooling fluid 316A is provided to the cooling device 314 at a temperature of approximately 50 degrees Celsius. In some embodiments, the cooling fluid 316A is provided to the cooling device 314 at a flowrate between approximately 0.3 liters per minute (L/m) and approximately 0.7 L/m. In some embodiments, the cooling fluid 316A is provided to the cooling device 314 at a flowrate of approximately 0.5 L/m. Warmed cooling fluid 316B may flow from the cooling device 314. In some embodiments, the cooling fluid 316B flows from the cooling device 314 at a temperature between approximately 52 degrees Celsius and approximately 60 degrees Celsius. In some embodiments, the cooling fluid 316B flows from the cooling device 314 at a temperature of approximately 56 degrees Celsius. In some embodiments, the cooling fluid 316B flows from the cooling device 314 at a temperature of approximately 55.8 degrees Celius. The cooling fluid 316B may flow from the cooling device 314 at the same flow rate that cooling fluid 316A is provided to the cooling device. The conduction of heat from the computing component 322 to the cooling fluid may maintain the computing component 322 at a safe operable temperature.

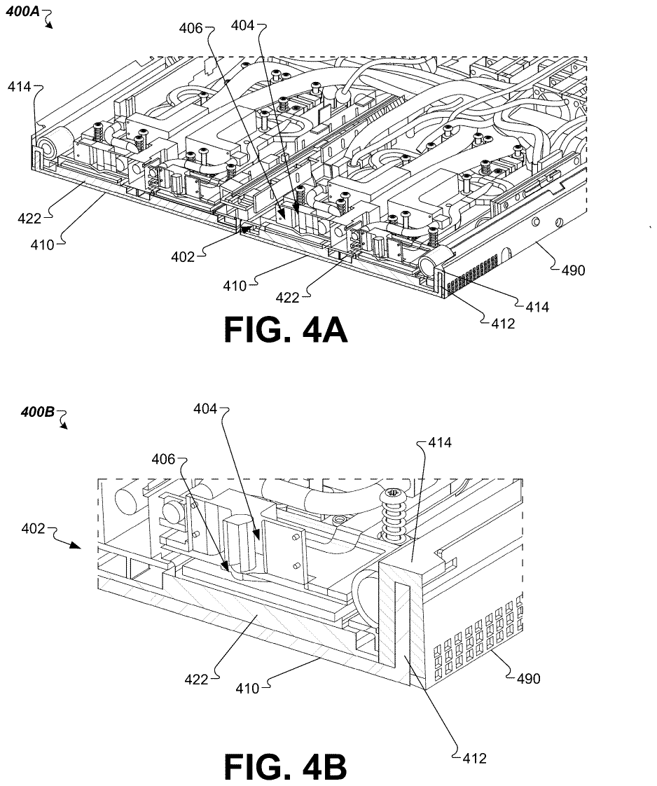

FIGS. 4A-4B illustrate simplified perspective cutaway views of an example computing circuit cooled using a heat-conducting component, in accordance with at least some embodiments. Referring to FIG. 4A, a cutaway perspective view 400A is shown. Referring to FIG. 4B, a cutaway perspective view 400B is shown. View 400B may be a detailed view of components shown in view 400A. Components described with respect to FIGS. 4A and 4B may correspond to other components described herein above having similar/same reference numbers. In some embodiments, a computing circuit is housed within a chassis 490. The computing circuit may be a server, such as a server in a datacenter, etc. In some embodiments, multiple server components 404 are coupled on a top side of a PCB 402. The computing components 404 may be cooled using cold plates 406 that are to receive a flow of coolant. In some embodiments, at least one computing component 422 is coupled on a bottom side of PCB 402. In some embodiments, multiple computing components 422 are coupled on a bottom side of PCB 402. There may not be enough space between the computing components 422 and the bottom of the chassis 490 for conventional cold plate cooling of the computing components 422. In some embodiments, one or more heat-conducting components 410 is used to cool the computing components 422. Multiple heat-conducting components 410 may be used in some embodiments. The heat-conducting component 410 may be a vapor chamber or a solid body of heat-conducting material as described herein above. Heat from the computing components 422 may be transported away from the server components 422 and from the bottom side of the PCB 402 to a top side of the PCB 402.

In some embodiments, heat is transported from the computing components 422 to a cooling device 414. The cooling device 414 may be disposed adjacent to a side wall of the chassis 490. The cooling device 414 may be disposed at least partially on a bottom side of PCB 402 and at least partially on a top side of PCB 402. In some embodiments, the cooling device 414 mates with a heat-dissipation feature 412 of the heat-conducting component 410. The heat-dissipation feature 412 may be disposed at least partially within an opening formed by the cooling device 414. The heat-dissipation feature 412 may be disposed at least partially on a bottom side of PCB 402 and at least partially on a top side of PCB 402. In some embodiments, a thermal interface may be disposed between the outer surface(s) of the heat-dissipation feature 412 and the inner surface(s) of the cooling device 414. The cooling device 414 may receive a flow of coolant. Heat from the server components 422 may be provided to the flow of coolant by the heat-conducting component 410 and the cooling device 414. The heat may be carried away by the coolant, such as to a heat exchanger, etc.

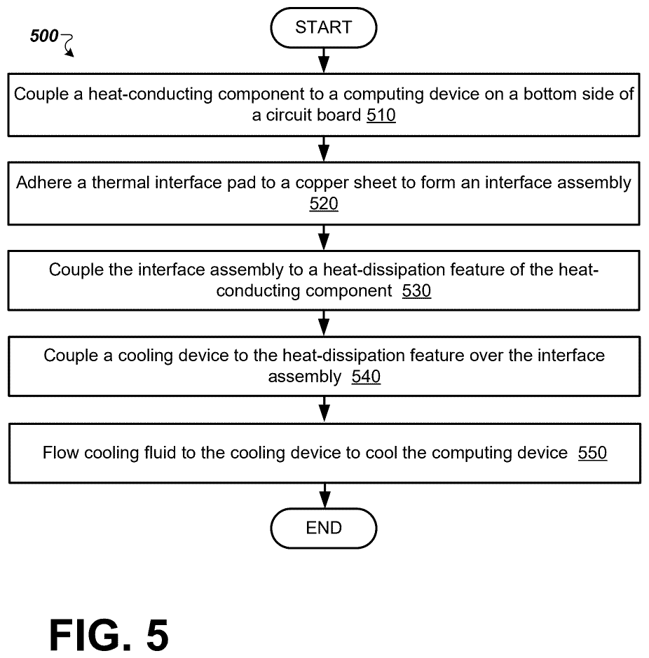

FIG. 5 is a flow diagram of an example method 500 of assembling and using a heat-conducting component to cool a computing component, in accordance with at least some embodiments. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 510, a heat-conducting component (e.g., 110, 210, 410, etc.) is coupled to a computing component on a bottom side of a circuit board. The circuit board may be disposed within a chassis, such as a server chassis. The heat-conducting component may include a main body that is coupled with the computing component. The heat-conducting component may be a vapor chamber or a solid body of heat-conducting material as described herein. In some embodiments, the heat-conducting component includes a heat-dissipation feature protruding from the main body. The heat-dissipation feature may protrude from the main body proximate an edge of the heat-conducting component.

At operation 520, a thermal interface pad is adhered to a copper sheet (e.g., a copper layer) to form an interface assembly. In some embodiments, the thermal interface pad is a soft compressible pad to improve heat transfer. For example, the thermal interface pad may be made of silicone or an elastomer. In some embodiments, the copper sheet includes slits into which the pad can squeeze responsive to a compressive force.

At operation 530, the interface assembly is coupled to the heat-dissipation feature of the heat-conducting component. In some embodiments, the heat-dissipation feature is inserted into an opening formed by the interface assembly. The copper sheet may protect the thermal interface pad from damage during insertion of the heat-dissipation feature into the opening.

At operation 540, a cooling device is coupled to the heat-dissipation feature over the interface assembly. In some embodiments, the interface assembly is disposed between one or more outer surfaces of the heat-dissipation feature and one or more inner surfaces of the cooling device. Installation of the cooling device onto the heat-dissipation feature may cause the interface assembly to compress. The thermal interface pad may at least partially squeeze into the slits formed in the copper sheet responsive to the compressive installation force. In some embodiments, the cooling device is configured to receive a flow of cooling fluid (e.g., liquid coolant, two-phase coolant, etc.).

At operation 550, cooling fluid is flowed to the cooling device to cool the computing component. In some embodiments, heat from the cooling device on the bottom of the circuit board is transported through the heat-conducting component and/or the cooling device to coolant on the top side of the circuit board. The heat from the computing component may be provided to the flow of cooling fluid and transported away, such as to a heat exchanger.

### Servers and Data Centers

The following figures set forth, without limitation, exemplary network server and data center based systems that can be used to implement at least one embodiment.

Datacenters may include multiple network switches in a particular topology, such as a fat tree topology, a slim fly topology, a dragonfly topology, and/or the like. The specifications and makeup of the network switches in the topology affects the overall network performance (e.g., bandwidth capability) of the datacenter.

### Example Data Center Environment

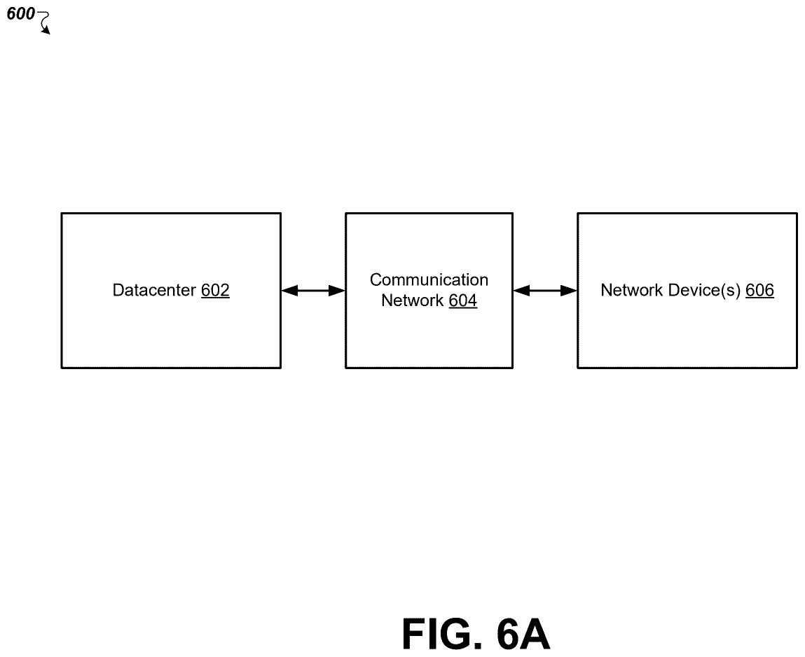

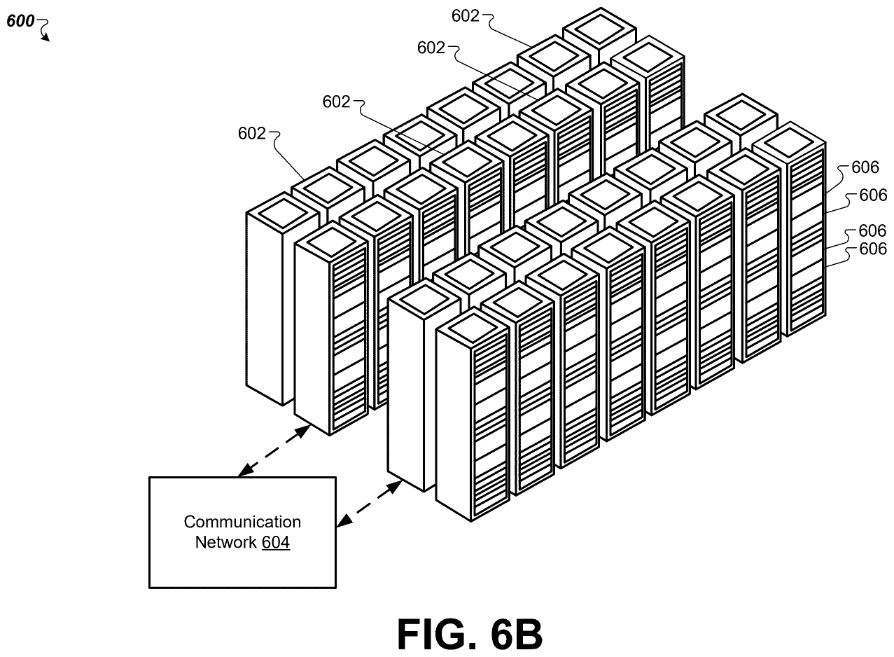

As described above, datacenters, high performance computing clusters, and/or the like are often formed of various computing components or networked devices, and communication networks formed of electrical and/or optical devices may be used to enable communication between the networked devices forming these implementations. With reference to FIGS. 6A-6B, for example, a network architecture 600 may include a datacenter 602, a communication network 604, and network device(s) 606. The network architecture 600 may illustrate a general computing architecture within which more specific systems and/or subsystems may function. Although described hereinafter with reference to a network architecture 600 and/or datacenter 602 within which the embodiments of the present disclosure may be implemented, the present disclosure contemplates that the transceiver resiliency devices and techniques described herein may be applicable to any communication implementation without limitation.

For example, the datacenter 602 may be a centralized facility designed to house computing resources and related components. The datacenter 602 may operate to support the infrastructure required for advanced computational tasks, for efficient, secure, and reliable operations. The datacenter 602 may include the building and structural components, including power supplies, cooling systems, fire suppression systems, and physical security measures that are configured to maintain optimal operating conditions and/or protect the equipment from environmental hazards and unauthorized access. An example datacenter 602 may include high-performance servers or compute nodes, often arranged in racks, such as those illustrated in FIG. 6B, and connected through high-speed networks as described herein. These servers may include processors (e.g., central processing units (CPUs), graphics processing units (GPUs), data processing units (DPUs) and/or the like), memory (e.g., RAM), and storage solutions (e.g., hard disk drives (HDDs), solid state drives (SSDs), and/or the like. The hardware configuration may be designed for parallel processing and high throughput, catering to the demands of high-performance computing (HPC) applications.

The datacenter 602 may include high-speed network equipment, such as network switches, routers, firewalls, and/or the like to facilitate fast and secure data transmission within the datacenter 602 (e.g., between the servers or compute nodes) and between external networks. The datacenter 602 may facilitate communication between servers or compute nodes through a network topology that ensures efficient data exchange, minimizes latency, and maximizes bandwidth. The network topology may dictate how various network devices, such as switches and routers, are interconnected for data flow. By implementing an effective network topology, the datacenter 602 may support high-performance computing tasks. Examples of various network topologies may include hierarchical networking topologies such as the fat tree topology, Slim Fly topology, Dragonfly topology, and/or the like.

The communication network 604 may communicably couple the datacenter 602 with network device(s) 606 and other external devices for data exchange and connectivity. Examples of the communication network 604 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. The ability of the communication network 604 to incorporate multiple network types and configurations may allow the datacenter 602 to adapt to diverse application needs, from general data communication to specialized HPC tasks. As described herein, the communication network 604 may leverage various optical components to establish communication links (e.g., communicably couple) between components in the architecture 600. As such, the communication network 604 may include various optical devices, transceivers, modules, and/or the like that are configured to generate optical signals (e.g., provide optical transmitter functionality) and/or receive optical signals (e.g., provide optical receiver functionality).

The network device(s) 606 may include a variety of computing devices capable of transmitting and receiving signals over the communication network 604. The network device(s) 606 may range from personal computing devices to complex server configurations. Examples include Personal Computers (PCs), laptops, tablets, smartphones, and servers. The network device(s) 606 may facilitate user interactions with the datacenter 602, allowing for data input, retrieval, and processing from remote locations. In addition to individual computing devices, the network device(s) 606 may also include collections of servers or additional datacenters. For instance, these could be other datacenters similar to or the same as datacenter 602. Such an interconnection may allow for the formation of a distributed computing environment for improved redundancy, load balancing, and disaster recovery capabilities. By linking multiple datacenters, the network architecture 600 may leverage geographically dispersed resources, optimizing performance and ensuring high availability.

As described herein, the datacenter 602 and/or the network device(s) 606 may include storage devices and processing circuitry for executing computing tasks, such as controlling the flow of data internally and over the communication network 604. The processing circuitry may include software, hardware, or a combination thereof. For example, the processing circuitry may include a memory containing executable instructions and a processor (e.g., a microprocessor) that executes these instructions. The memory may correspond to any suitable type of memory device or collection of memory devices configured to store instructions. Non-limiting examples of suitable memory devices include Flash memory, Random Access Memory (RAM), Read Only Memory (ROM), variants thereof, combinations thereof, or similar technologies. In specific embodiments, the memory and processor may be integrated into a common device, such as a microprocessor with integrated memory. Additionally, or alternatively, the processing circuitry may comprise hardware components, such as an application-specific integrated circuit (ASIC). Other non-limiting examples of processing circuitry include Integrated Circuit (IC) chips, CPUs, GPUs, microprocessors, Field Programmable Gate Arrays (FPGAs), collections of logic gates or transistors, resistors, capacitors, inductors, and diodes. Some or all of the processing circuitry may be provided on a Printed Circuit Board (PCB) or a collection of PCBs. It should be appreciated that any appropriate type of electrical component or collection of electrical components may be suitable for inclusion in the processing circuitry.

In addition, although not explicitly shown, the present disclosure contemplates that the datacenter 602 and network device(s) 606 may include one or more communication interfaces for facilitating wired and/or wireless communication between one another and other unillustrated elements of the network architecture 600. These communication interfaces may include a variety of technologies, including but not limited to Ethernet ports, fiber optic connections, Wi-Fi® transceivers, Bluetooth® modules, and cellular communication modules for integration and interoperability among the various components within the network architecture 600.

Furthermore, the present disclosure contemplates that the network architecture 600 may include additional components and functionalities. For example, the network architecture may include, without limitation, additional processing units, specialized accelerators (such as Tensor Processing Units or TPUs), enhanced security modules, and redundant power supplies. The inclusion of these elements may be intended to ensure that the network architecture 600 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the network architecture 600.

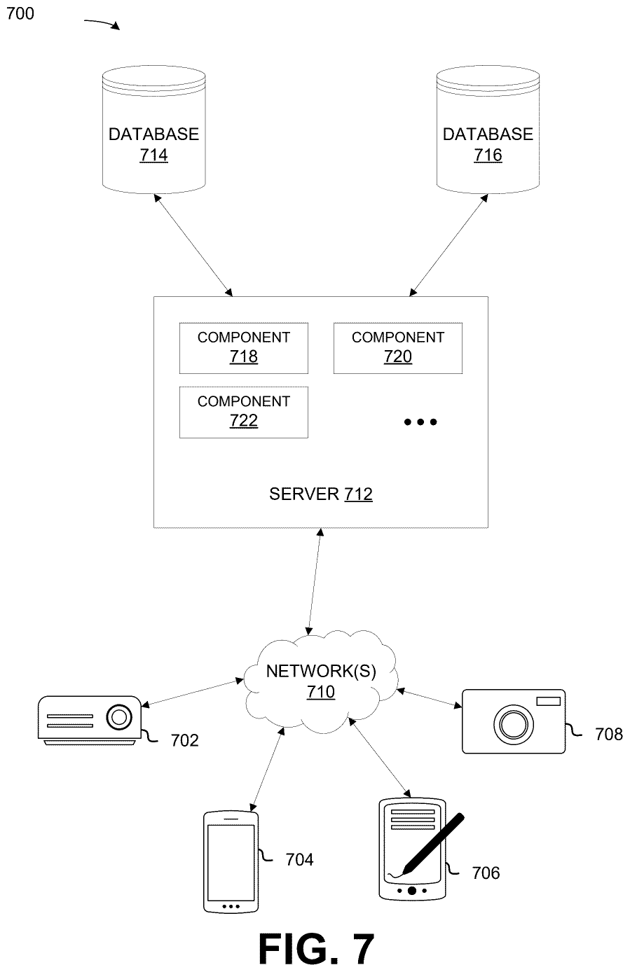

FIG. 7 illustrates a distributed system 700, in accordance with at least some embodiments. In at least one embodiment, distributed system 700 includes one or more client computing devices 702, 704, 706, and 708, which are configured to execute and operate a client application such as a web browser, proprietary client, and/or variations thereof over one or more network(s) 710. In at least one embodiment, server 712 may be communicatively coupled with remote client computing devices 702, 704, 706, and 708 via network 710. In some embodiments, server 712 includes one or more computing components cooled using a heat-conducting component as described herein above.

In at least one embodiment, server 712 may be adapted to run one or more services or software applications such as services and applications that may manage session activity of single sign-on (SSO) access across multiple data centers. In at least one embodiment, server 712 may also provide other services or software applications can include non-virtual and virtual environments. In at least one embodiment, these services may be offered as web-based or cloud services or under a Software as a Service (SaaS) model to users of client computing devices 702, 704, 706, and/or 708. In at least one embodiment, users operating client computing devices 702, 704, 706, and/or 708 may in turn utilize one or more client applications to interact with server 712 to utilize services provided by these components.

In at least one embodiment, software components 718, 720 and 722 of system 700 are implemented on server 712. In at least one embodiment, one or more components of system 700 and/or services provided by these components may also be implemented by one or more of client computing devices 702, 704, 706, and/or 708. In at least one embodiment, users operating client computing devices may then utilize one or more client applications to use services provided by these components. In at least one embodiment, these components may be implemented in hardware, firmware, software, or combinations thereof. It should be appreciated that various different system configurations are possible, which may be different from distributed system 700. The embodiment shown in FIG. 7 is thus one example of a distributed system for implementing an embodiment system and is not intended to be limiting.

In at least one embodiment, client computing devices 702, 704, 706, and/or 708 may include various types of computing systems. In at least one embodiment, a client computing device may include portable handheld devices (e.g., an iPhone®, cellular telephone, an iPad®, computing tablet, a personal digital assistant (PDA)) or wearable devices (e.g., a Google Glass® head mounted display), running software such as Microsoft Windows Mobile®, and/or a variety of mobile operating systems such as iOS, Windows Phone, Android, BlackBerry 10, Palm OS, and/or variations thereof. In at least one embodiment, devices may support various applications such as various Internet-related apps, e-mail, short message service (SMS) applications, and may use various other communication protocols. In at least one embodiment, client computing devices may also include general purpose personal computers including, by way of example, personal computers and/or laptop computers running various versions of Microsoft Windows®, Apple Macintosh®, and/or Linux operating systems. In at least one embodiment, client computing devices can be workstation computers running any of a variety of commercially-available UNIX® or UNIX-like operating systems, including without limitation a variety of GNU/Linux operating systems, such as Google Chrome OS. In at least one embodiment, client computing devices may also include electronic devices such as a thin-client computer, an Internet-enabled gaming system (e.g., a Microsoft Xbox gaming console with or without a Kinect® gesture input device), and/or a personal messaging device, capable of communicating over network(s) 710. Although distributed system 700 in FIG. 7 is shown with four client computing devices, any number of client computing devices may be supported. Other devices, such as devices with sensors, etc., may interact with server 712.

In at least one embodiment, network(s) 710 in distributed system 700 may be any type of network that can support data communications using any of a variety of available protocols, including without limitation TCP/IP (transmission control protocol/Internet protocol), SNA (systems network architecture), IPX (Internet packet exchange), AppleTalk, and/or variations thereof. In at least one embodiment, network(s) 710 can be a local area network (LAN), networks based on Ethernet, Token-Ring, a wide-area network, Internet, a virtual network, a virtual private network (VPN), an intranet, an extranet, a public switched telephone network (PSTN), an infra-red network, a wireless network (e.g., a network operating under any of the Institute of Electrical and Electronics (IEEE) 802.11 suite of protocols, Bluetooth®, and/or any other wireless protocol), and/or any combination of these and/or other networks.

In at least one embodiment, server 712 may be composed of one or more general purpose computers, specialized server computers (including, by way of example, PC (personal computer) servers, UNIX® servers, mid-range servers, mainframe computers, rack-mounted servers, etc.), server farms, server clusters, or any other appropriate arrangement and/or combination. In at least one embodiment, server 712 can include one or more virtual machines running virtual operating systems, or other computing architectures involving virtualization. In at least one embodiment, one or more flexible pools of logical storage devices can be virtualized to maintain virtual storage devices for a server. In at least one embodiment, virtual networks can be controlled by server 712 using software defined networking. In at least one embodiment, server 712 may be adapted to run one or more services or software applications.

In at least one embodiment, server 712 may run any operating system, as well as any commercially available server operating system. In at least one embodiment, server 712 may also run any of a variety of additional server applications and/or mid-tier applications, including HTTP (hypertext transport protocol) servers, FTP (file transfer protocol) servers, CGI (common gateway interface) servers, JAVA® servers, database servers, and/or variations thereof. In at least one embodiment, exemplary database servers include without limitation those commercially available from Oracle, Microsoft, Sybase, IBM (International Business Machines), and/or variations thereof.

In at least one embodiment, server 712 may include one or more applications to analyze and consolidate data feeds and/or event updates received from users of client computing devices 702, 704, 706, and 708. In at least one embodiment, data feeds and/or event updates may include, but are not limited to, Twitter® feeds, Facebook® updates or real-time updates received from one or more third party information sources and continuous data streams, which may include real-time events related to sensor data applications, financial tickers, network performance measuring tools (e.g., network monitoring and traffic management applications), clickstream analysis tools, automobile traffic monitoring, and/or variations thereof. In at least one embodiment, server 712 may also include one or more applications to display data feeds and/or real-time events via one or more display devices of client computing devices 702, 704, 706, and 708.

In at least one embodiment, distributed system 700 may also include one or more databases 714 and 716. In at least one embodiment, databases may provide a mechanism for storing information such as user interactions information, usage patterns information, adaptation rules information, and other information. In at least one embodiment, databases 714 and 716 may reside in a variety of locations. In at least one embodiment, one or more of databases 714 and 716 may reside on a non-transitory storage medium local to (and/or resident in) server 712. In at least one embodiment, databases 714 and 716 may be remote from server 712 and in communication with server 712 via a network-based or dedicated connection. In at least one embodiment, databases 714 and 716 may reside in a storage-area network (SAN). In at least one embodiment, any necessary files for performing functions attributed to server 712 may be stored locally on server 712 and/or remotely, as appropriate. In at least one embodiment, databases 714 and 716 may include relational databases, such as databases that are adapted to store, update, and retrieve data in response to SQL-formatted commands.

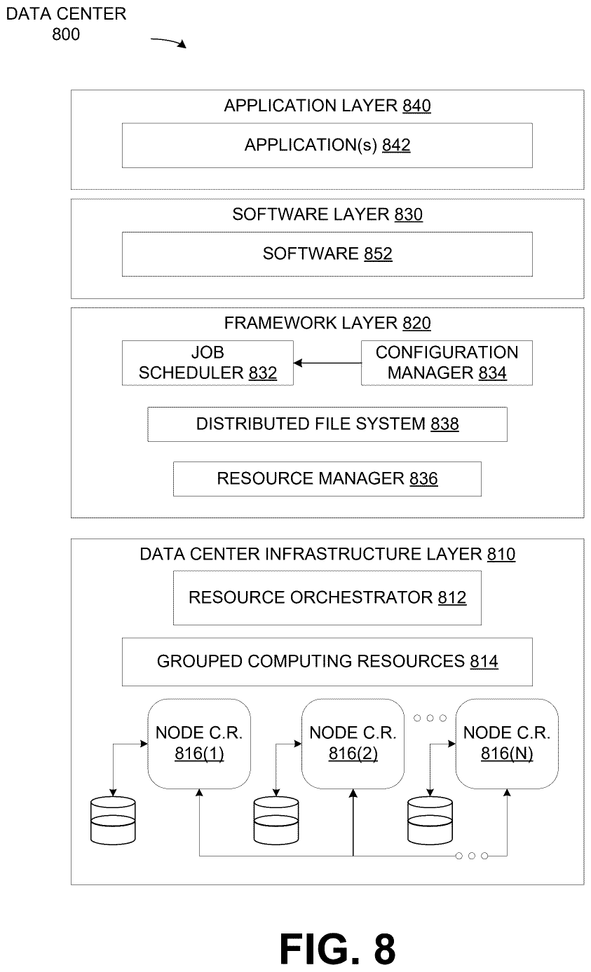

FIG. 8 illustrates an exemplary data center 800, in accordance with at least some embodiments. In at least one embodiment, data center 800 includes, without limitation, a data center infrastructure layer 810, a framework layer 820, a software layer 830 and an application layer 840.

In at least one embodiment, as shown in FIG. 8, data center infrastructure layer 810 may include a resource orchestrator 812, grouped computing resources 814, and node computing resources (“node C.R.s”) 816(1)-816(N), where “N” represents any whole, positive integer. In at least one embodiment, node C.R.s 816(1)-816(N) may include, but are not limited to, any number of central processing units (“CPUs”) or other processors (including accelerators, field programmable gate arrays (“FPGAs”), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 816(1)-816(N) may be a server having one or more of above-mentioned computing resources.

In at least one embodiment, grouped computing resources 814 may include separate groupings of node C.R.s housed within one or more racks (not shown), or many racks housed in data centers at various geographical locations (also not shown). Separate groupings of node C.R.s within grouped computing resources 814 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 812 may configure or otherwise control one or more node C.R.s 816(1)-816(N) and/or grouped computing resources 814. In at least one embodiment, resource orchestrator 812 may include a software design infrastructure (“SDI”) management entity for data center 800. In at least one embodiment, resource orchestrator 812 may include hardware, software or some combination thereof.

In at least one embodiment, as shown in FIG. 8, framework layer 820 includes, without limitation, a job scheduler 832, a configuration manager 834, a resource manager 836 and a distributed file system 838. In at least one embodiment, framework layer 820 may include a framework to support software 852 of software layer 830 and/or one or more application(s) 842 of application layer 840. In at least one embodiment, software 852 or application(s) 842 may respectively include web-based service software or applications, such as those provided by Amazon Web Services, Google Cloud and Microsoft Azure. In at least one embodiment, framework layer 820 may be, but is not limited to, a type of free and open-source software web application framework such as Apache Spark™ (hereinafter “Spark”) that may utilize distributed file system 838 for large-scale data processing (e.g., “big data”). In at least one embodiment, job scheduler 832 may include a Spark driver to facilitate scheduling of workloads supported by various layers of data center 800. In at least one embodiment, configuration manager 834 may be capable of configuring different layers such as software layer 830 and framework layer 820, including Spark and distributed file system 838 for supporting large-scale data processing. In at least one embodiment, resource manager 836 may be capable of managing clustered or grouped computing resources mapped to or allocated for support of distributed file system 838 and job scheduler 832. In at least one embodiment, clustered or grouped computing resources may include grouped computing resource 814 at data center infrastructure layer 810. In at least one embodiment, resource manager 836 may coordinate with resource orchestrator 812 to manage these mapped or allocated computing resources.

In at least one embodiment, software 852 included in software layer 830 may include software used by at least portions of node C.R.s 816(1)-816(N), grouped computing resources 814, and/or distributed file system 838 of framework layer 820. One or more types of software may include, but are not limited to, Internet web page search software, e-mail virus scan software, database software, and streaming video content software.

In at least one embodiment, application(s) 842 included in application layer 840 may include one or more types of applications used by at least portions of node C.R.s 816(1)-816(N), grouped computing resources 814, and/or distributed file system 838 of framework layer 820. In at least one or more types of applications may include, without limitation, CUDA applications, 5G network applications, artificial intelligence application, data center applications, and/or variations thereof.

In at least one embodiment, any of configuration manager 834, resource manager 836, and resource orchestrator 812 may implement any number and type of self-modifying actions based on any amount and type of data acquired in any technically feasible fashion. In at least one embodiment, self-modifying actions may relieve a data center operator of data center 800 from making possibly bad configuration decisions and possibly avoiding underutilized and/or poor performing portions of a data center.

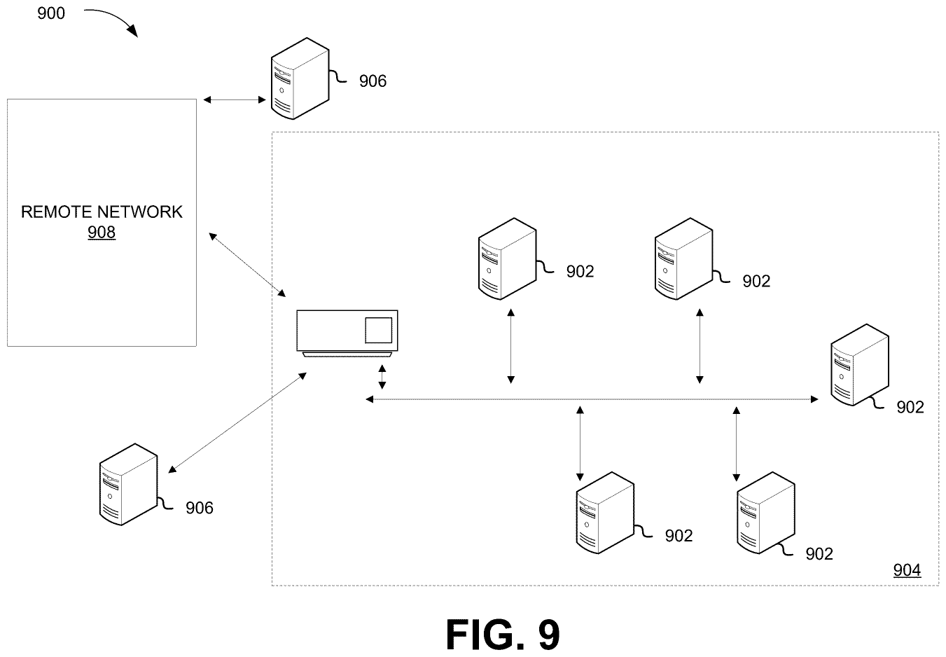

FIG. 9 illustrates a client-server network 904 formed by a plurality of network server computers 902 which are interlinked, in accordance with at least one embodiment. In at least one embodiment, each network server computer 902 stores data accessible to other network server computers 902 and to client computers 906 and networks 908 which link into a wide area network 904. In at least one embodiment, configuration of a client-server network 904 may change over time as client computers 906 and one or more networks 908 connect and disconnect from a network 904, and as one or more trunk line server computers 902 are added or removed from a network 904. In at least one embodiment, when a client computer 906 and a network 908 are connected with network server computers 902, client-server network includes such client computer 906 and network 908. In at least one embodiment, the term computer includes any device or machine capable of accepting data, applying prescribed processes to data, and supplying results of processes.

In at least one embodiment, client-server network 904 stores information which is accessible to network server computers 902, remote networks 908 and client computers 906. In at least one embodiment, network server computers 902 are formed by main frame computers minicomputers, and/or microcomputers having one or more processors each. In at least one embodiment, server computers 902 are linked together by wired and/or wireless transfer media, such as conductive wire, fiber optic cable, and/or microwave transmission media, satellite transmission media or other conductive, optic or electromagnetic wave transmission media. In at least one embodiment, client computers 906 access a network server computer 902 by a similar wired or a wireless transfer medium. In at least one embodiment, a client computer 906 may link into a client-server network 904 using a modem and a standard telephone communication network. In at least one embodiment, alternative carrier systems such as cable and satellite communication systems also may be used to link into client-server network 904. In at least one embodiment, other private or time-shared carrier systems may be used. In at least one embodiment, network 904 is a global information network, such as the Internet. In at least one embodiment, network is a private intranet using similar protocols as the Internet, but with added security measures and restricted access controls. In at least one embodiment, network 904 is a private, or semi-private network using proprietary communication protocols.

In at least one embodiment, client computer 906 is any end user computer, and may also be a mainframe computer, mini-computer or microcomputer having one or more microprocessors. In at least one embodiment, server computer 902 may at times function as a client computer accessing another server computer 902. In at least one embodiment, remote network 908 may be a local area network, a network added into a wide area network through an independent service provider (ISP) for the Internet, or another group of computers interconnected by wired or wireless transfer media having a configuration which is either fixed or changing over time. In at least one embodiment, client computers 906 may link into and access a network 904 independently or through a remote network 908.

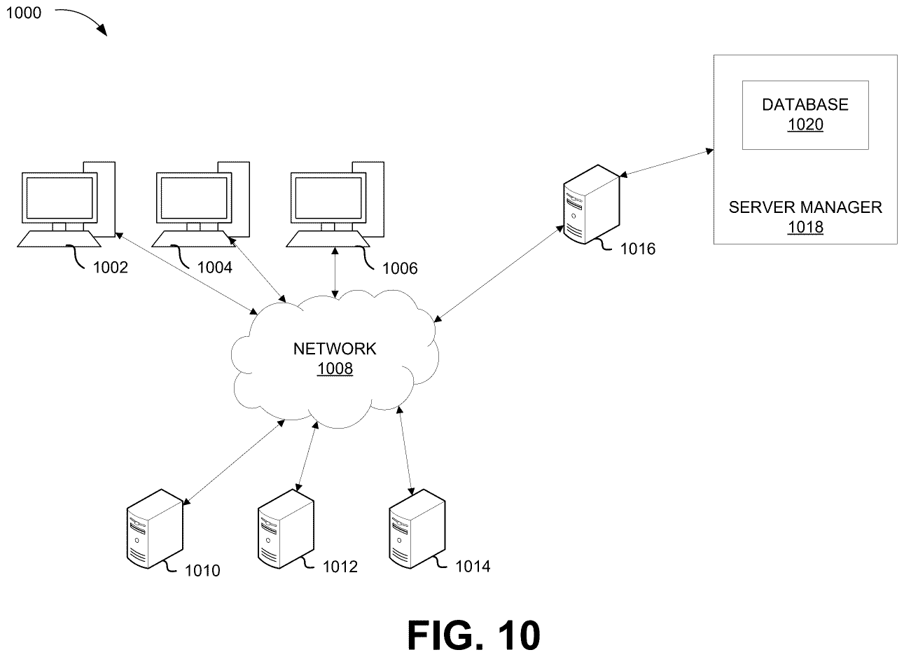

FIG. 10 illustrates a computer network 1008 connecting one or more computing machines, in accordance with at least some embodiments. In at least one embodiment, network 1008 may be any type of electronically connected group of computers including, for instance, the following networks: Internet, Intranet, Local Area Networks (LAN), Wide Area Networks (WAN) or an interconnected combination of these network types. In at least one embodiment, connectivity within a network 1008 may be a remote modem, Ethernet (IEEE 802.3), Token Ring (IEEE 802.5), Fiber Distributed Datalink Interface (FDDI), Asynchronous Transfer Mode (ATM), or any other communication protocol. In at least one embodiment, computing devices linked to a network may be desktop, server, portable, handheld, set-top box, personal digital assistant (PDA), a terminal, or any other desired type or configuration. In at least one embodiment, depending on their functionality, network connected devices may vary widely in processing power, internal memory, and other performance aspects. In at least one embodiment, communications within a network and to or from computing devices connected to a network may be either wired or wireless. In at least one embodiment, network 1008 may include, at least in part, the world-wide public Internet which generally connects a plurality of users in accordance with a client-server model in accordance with a transmission control protocol/internet protocol (TCP/IP) specification. In at least one embodiment, client-server network is a dominant model for communicating between two computers. In at least one embodiment, a client computer (“client”) issues one or more commands to a server computer (“server”). In at least one embodiment, server fulfills client commands by accessing available network resources and returning information to a client pursuant to client commands. In at least one embodiment, client computer systems and network resources resident on network servers are assigned a network address for identification during communications between elements of a network. In at least one embodiment, communications from other network connected systems to servers will include a network address of a relevant server/network resource as part of communication so that an appropriate destination of a data/request is identified as a recipient. In at least one embodiment, when a network 1008 comprises the global Internet, a network address is an IP address in a TCP/IP format which may, at least in part, route data to an e-mail account, a website, or other Internet tool resident on a server. In at least one embodiment, information and services which are resident on network servers may be available to a web browser of a client computer through a domain name (e.g. www.site.com) which maps to an IP address of a network server.

In at least one embodiment, a plurality of clients 1002, 1004, and 1006 are connected to a network 1008 via respective communication links. In at least one embodiment, each of these clients may access a network 1008 via any desired form of communication, such as via a dial-up modem connection, cable link, a digital subscriber line (DSL), wireless or satellite link, or any other form of communication. In at least one embodiment, each client may communicate using any machine that is compatible with a network 1008, such as a personal computer (PC), work station, dedicated terminal, personal data assistant (PDA), or other similar equipment. In at least one embodiment, clients 1002, 1004, and 1006 may or may not be located in a same geographical area.

In at least one embodiment, a plurality of servers 1010, 1012, and 1014 are connected to a network 1008 to serve clients that are in communication with a network 1008. In at least one embodiment, each server is typically a powerful computer or device that manages network resources and responds to client commands. In at least one embodiment, servers include computer readable data storage media such as hard disk drives and RAM memory that store program instructions and data. In at least one embodiment, servers 1010, 1012, 1014 run application programs that respond to client commands. In at least one embodiment, server 1010 may run a web server application for responding to client requests for HTML pages and may also run a mail server application for receiving and routing electronic mail. In at least one embodiment, other application programs, such as an FTP server or a media server for streaming audio/video data to clients may also be running on a server 1010. In at least one embodiment, different servers may be dedicated to performing different tasks. In at least one embodiment, server 1010 may be a dedicated web server that manages resources relating to web sites for various users, whereas a server 1012 may be dedicated to provide electronic mail (email) management. In at least one embodiment, other servers may be dedicated for media (audio, video, etc.), file transfer protocol (FTP), or a combination of any two or more services that are typically available or provided over a network. In at least one embodiment, each server may be in a location that is the same as or different from that of other servers. In at least one embodiment, there may be multiple servers that perform mirrored tasks for users, thereby relieving congestion or minimizing traffic directed to and from a single server. In at least one embodiment, servers 1010, 1012, 1014 are under control of a web hosting provider in a business of maintaining and delivering third party content over a network 1008.

In at least one embodiment, web hosting providers deliver services to two different types of clients. In at least one embodiment, one type, which may be referred to as a browser, requests content from servers 1010, 1012, 1014 such as web pages, email messages, video clips, etc. In at least one embodiment, a second type, which may be referred to as a user, hires a web hosting provider to maintain a network resource such as a web site, and to make it available to browsers. In at least one embodiment, users contract with a web hosting provider to make memory space, processor capacity, and communication bandwidth available for their desired network resource in accordance with an amount of server resources a user desires to utilize.

In at least one embodiment, in order for a web hosting provider to provide services for both of these clients, application programs which manage a network resources hosted by servers must be properly configured. In at least one embodiment, program configuration process involves defining a set of parameters which control, at least in part, an application program's response to browser requests and which also define, at least in part, a server resources available to a particular user.

In one embodiment, an intranet server 1016 is in communication with a network 1008 via a communication link. In at least one embodiment, intranet server 1016 is in communication with a server manager 1018. In at least one embodiment, server manager 1018 comprises a database of an application program configuration parameters which are being utilized in servers 1010, 1012, 1014. In at least one embodiment, users modify a database 1020 via an intranet 1016, and a server manager 1018 interacts with servers 1010, 1012, 1014 to modify application program parameters so that they match a content of a database. In at least one embodiment, a user logs onto an intranet server 1016 by connecting to an intranet 1016 via computer 1002 and entering authentication information, such as a username and password.

In at least one embodiment, when a user wishes to sign up for new service or modify an existing service, an intranet server 1016 authenticates a user and provides a user with an interactive screen display/control panel that allows a user to access configuration parameters for a particular application program. In at least one embodiment, a user is presented with a number of modifiable text boxes that describe aspects of a configuration of a user's web site or other network resource. In at least one embodiment, if a user desires to increase memory space reserved on a server for its web site, a user is provided with a field in which a user specifies a desired memory space. In at least one embodiment, in response to receiving this information, an intranet server 1016 updates a database 1020. In at least one embodiment, server manager 1018 forwards this information to an appropriate server, and a new parameter is used during application program operation. In at least one embodiment, an intranet server 1016 is configured to provide users with access to configuration parameters of hosted network resources (e.g., web pages, email, FTP sites, media sites, etc.), for which a user has contracted with a web hosting service provider.

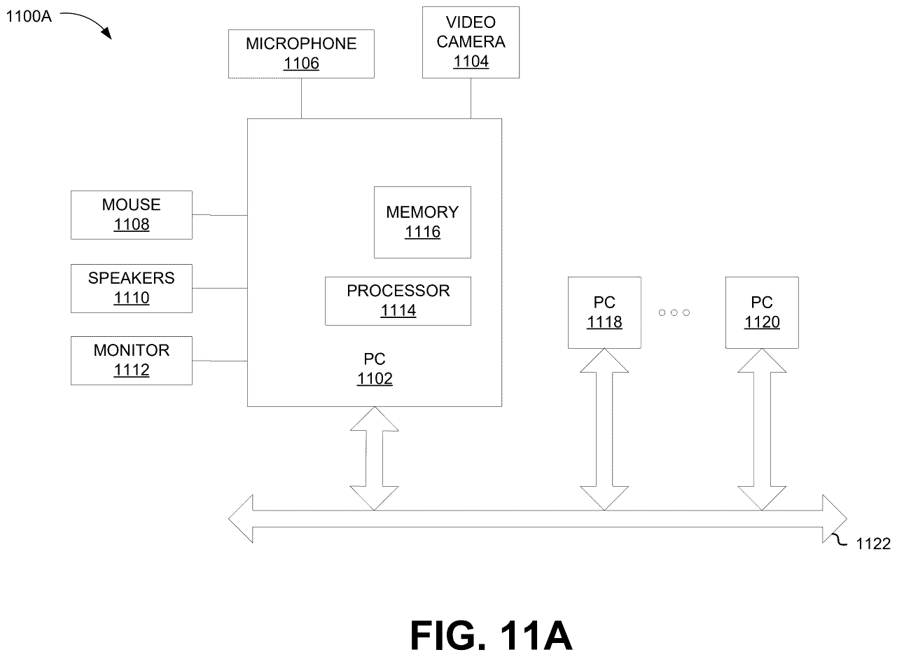

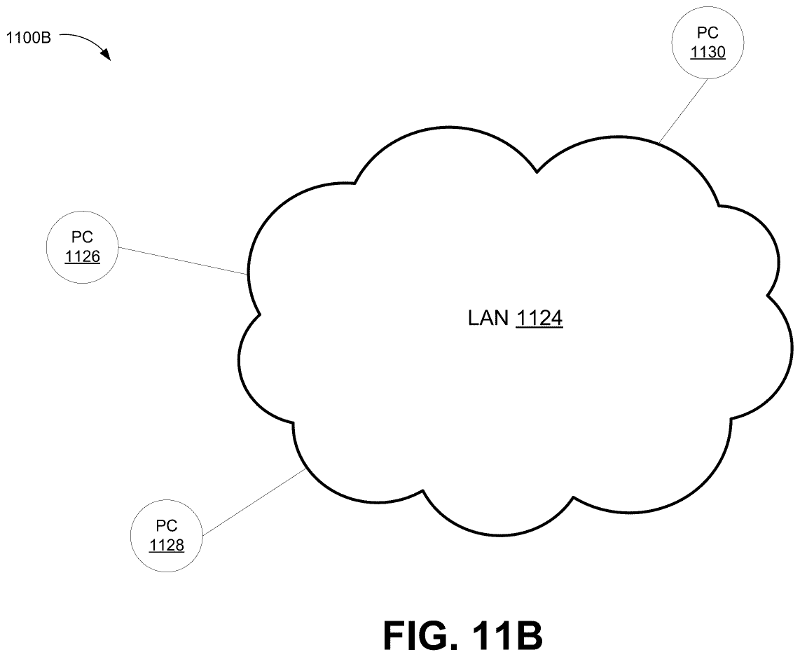

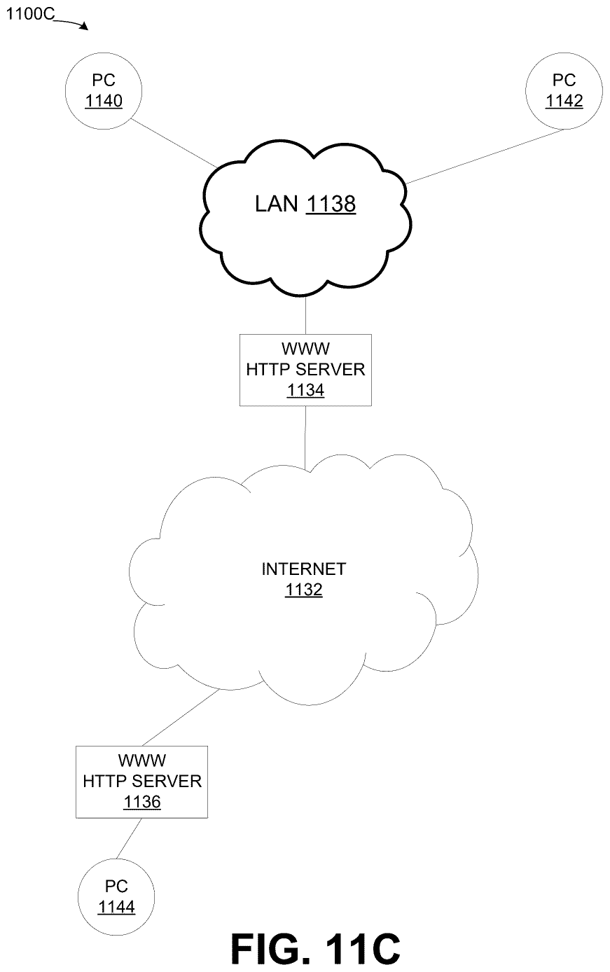

FIG. 11A illustrates a networked computer system 1100A, in accordance with at least some embodiments. In at least one embodiment, networked computer system 1100A comprises a plurality of nodes or personal computers (“PCs”) 1102, 1118, 1120. In at least one embodiment, personal computer or node 1102 comprises a processor 1114, memory 1116, video camera 1104, microphone 1106, mouse 1108, speakers 1110, and monitor 1112. In at least one embodiment, PCs 1102, 1118, 1120 may each run one or more desktop servers of an internal network within a given company, for instance, or may be servers of a general network not limited to a specific environment. In at least one embodiment, there is one server per PC node of a network, so that each PC node of a network represents a particular network server, having a particular network URL address. In at least one embodiment, each server defaults to a default web page for that server's user, which may itself contain embedded URLs pointing to further subpages of that user on that server, or to other servers or pages on other servers on a network.

In at least one embodiment, nodes 1102, 1118, 1120 and other nodes of a network are interconnected via medium 1122. In at least one embodiment, medium 1122 may be, a communication channel such as an Integrated Services Digital Network (“ISDN”). In at least one embodiment, various nodes of a networked computer system may be connected through a variety of communication media, including local area networks (“LANs”), plain-old telephone lines (“POTS”), sometimes referred to as public switched telephone networks (“PSTN”), and/or variations thereof. In at least one embodiment, various nodes of a network may also constitute computer system users inter-connected via a network such as the Internet. In at least one embodiment, each server on a network (running from a particular node of a network at a given instance) has a unique address or identification within a network, which may be specifiable in terms of an URL.

In at least one embodiment, a plurality of multi-point conferencing units (“MCUs”) may thus be utilized to transmit data to and from various nodes or “endpoints” of a conferencing system. In at least one embodiment, nodes and/or MCUs may be interconnected via an ISDN link or through a local area network (“LAN”), in addition to various other communications media such as nodes connected through the Internet. In at least one embodiment, nodes of a conferencing system may, in general, be connected directly to a communications medium such as a LAN or through an MCU, and that a conferencing system may comprise other nodes or elements such as routers, servers, and/or variations thereof.

In at least one embodiment, processor 1114 is a general-purpose programmable processor. In at least one embodiment, processors of nodes of networked computer system 1100A may also be special-purpose video processors. In at least one embodiment, various peripherals and components of a node such as those of node 1102 may vary from those of other nodes. In at least one embodiment, node 1118 and node 1120 may be configured identically to or differently than node 1102. In at least one embodiment, a node may be implemented on any suitable computer system in addition to PC systems.

FIG. 11B illustrates a networked computer system 1100B, in accordance with at least some embodiments. In at least one embodiment, system 1100B illustrates a network such as LAN 1124, which may be used to interconnect a variety of nodes that may communicate with each other. In at least one embodiment, attached to LAN 1124 are a plurality of nodes such as PC nodes 1126, 1128, 1130. In at least one embodiment, a node may also be connected to the LAN via a network server or other means. In at least one embodiment, system 1100B comprises other types of nodes or elements, for example including routers, servers, and nodes.

FIG. 11C illustrates a networked computer system 1100C, in accordance with at least some embodiments. In at least one embodiment, system 1100C illustrates a WWW system having communications across a backbone communications network such as Internet 1132, which may be used to interconnect a variety of nodes of a network. In at least one embodiment, WWW is a set of protocols operating on top of the Internet, and allows a graphical interface system to operate thereon for accessing information through the Internet. In at least one embodiment, attached to Internet 1132 in WWW are a plurality of nodes such as PCs 1140, 1142, 1144. In at least one embodiment, a node is interfaced to other nodes of WWW through a WWW HTTP server such as servers 1134, 1136. In at least one embodiment, PC 1144 may be a PC forming a node of network 1132 and itself running its server 1136, although PC 1144 and server 1136 are illustrated separately in FIG. 11C for illustrative purposes.

In at least one embodiment, WWW is a distributed type of application, characterized by WWW HTTP, WWW's protocol, which runs on top of the Internet's transmission control protocol/Internet protocol (“TCP/IP”). In at least one embodiment, WWW may thus be characterized by a set of protocols (i.e., HTTP) running on the Internet as its “backbone.”

In at least one embodiment, a web browser is an application running on a node of a network that, in WWW-compatible type network systems, allows users of a particular server or node to view such information and thus allows a user to search graphical and text-based files that are linked together using hypertext links that are embedded in documents or files available from servers on a network that understand HTTP. In at least one embodiment, when a given web page of a first server associated with a first node is retrieved by a user using another server on a network such as the Internet, a document retrieved may have various hypertext links embedded therein and a local copy of a page is created local to a retrieving user. In at least one embodiment, when a user clicks on a hypertext link, locally-stored information related to a selected hypertext link is typically sufficient to allow a user's machine to open a connection across the Internet to a server indicated by a hypertext link.

In at least one embodiment, more than one user may be coupled to each HTTP server, for example through a LAN such as LAN 1138 as illustrated with respect to WWW HTTP server 1134. In at least one embodiment, system 1100C may also comprise other types of nodes or elements. In at least one embodiment, a WWW HTTP server is an application running on a machine, such as a PC. In at least one embodiment, each user may be considered to have a unique “server,” as illustrated with respect to PC 1144. In at least one embodiment, a server may be considered to be a server such as WWW HTTP server 1134, which provides access to a network for a LAN or plurality of nodes or plurality of LANs. In at least one embodiment, there are a plurality of users, each having a desktop PC or node of a network, each desktop PC potentially establishing a server for a user thereof. In at least one embodiment, each server is associated with a particular network address or URL, which, when accessed, provides a default web page for that user. In at least one embodiment, a web page may contain further links (embedded URLs) pointing to further subpages of that user on that server, or to other servers on a network or to pages on other servers on a network.

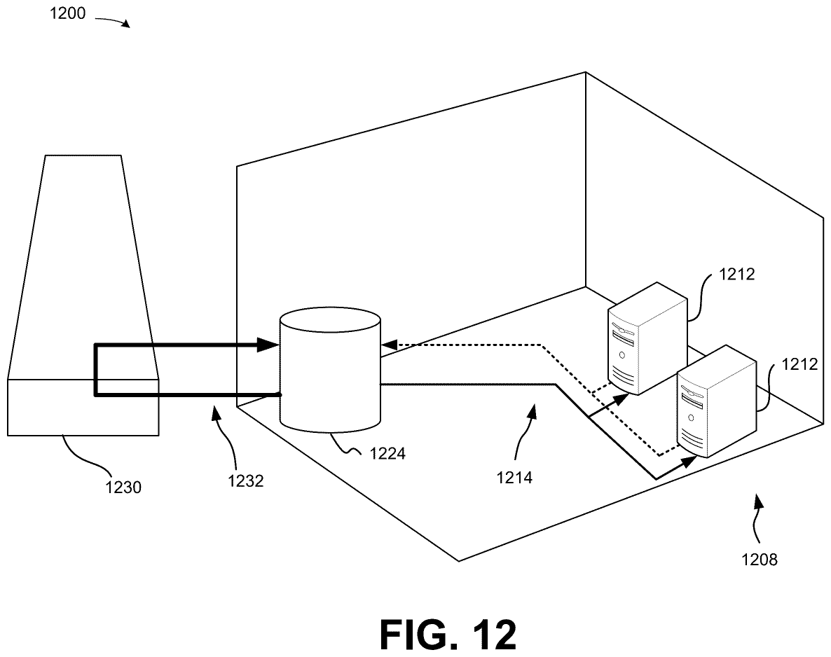

FIG. 12 illustrates an example datacenter cooling system 1200, according to at least some embodiments. In at least one embodiment, system 1200 includes a datacenter 1208 having one or more servers 1212. In at least one embodiment, servers 1212 are rack-based servers. For example, servers 1212 are disposed in one or more racks of datacenter 1208. In at least one embodiment, as discussed above with reference to FIG. 1, each server 1212 includes multiple computing components. In at least one embodiment, a server 1212 includes one or more computing components having greater than a threshold power density. Power density may be used to describe component power relative to component size. Computing components having greater than a threshold power density may be referred to as high-power computing components. In at least one embodiment, a high-power computing component may be a processing unit such as a central processing unit (CPU) or a graphical processing unit (GPU). In at least one embodiment, a high-power computing component may include a specialized or general processing device, such as aforementioned GPU and CPU, a field programmable gate array (FPGA), a data processing unit (DPU), and so on. In at least one embodiment, a high-power computing component of a server 1212 may put out more than a threshold amount of heat. Similarly, in at least one embodiment, a server 1212 includes one or more computing components having less than a threshold power density. Computing components having less than a threshold power density may be referred to as low-power computing components. In at least one embodiment, a low-power computing component of a server 1212 may output less than a threshold amount of heat. In at least one embodiment, low-power computing components of a server may include a power supply, a motherboard, memory, a network interface card (NIC), a solid state drive or hard drive, an audio card, and so on.

In at least one embodiment, computing components of servers 1212 are cooled by one or more cooling loops. In at least one embodiment, first cooling loop 1214 flows a first coolant to servers 1212 to cool one or more computing components of the servers 1212. In at least one embodiment, cooling loop 1214 includes conduits such as piping and/or tubing to flow coolant between a cooling distribution unit (CDU) 1224 and servers 1212. In at least one embodiment, first cooling loop 1214 may flow coolant along pipes, tubing, and/or one or more manifolds from first CDU 1224 to servers 1212 and back to first CDU 1224. In at least one embodiment, a first coolant may carry heat from servers 1212 to CDU 1224. In at least one embodiment, first coolant is provided to a cooling device in servers 1212 for cooling bottom side computing components via a heat-conducting component as described herein.

In at least one embodiment, a cold plate is a metal plate that can be attached to an electronic device (e.g., a computing component) such as a CPU or a GPU. In at least one embodiment, a cold plate is attached to an electronic device by an adhesive such as a thermal epoxy. In at least one embodiment, a cold plate is attached to an electronic device by one or more mechanical fasteners. In at least one embodiment, a cold plate can implement localized cooling of powered electronics by transferring heat from an electronic device to a liquid coolant that flows to a remote heat exchanger. In at least one embodiment, a cold plate includes a thick metal plate having one or more internal passages through which liquid coolant can flow. In at least one embodiment, a cold plate can be made of a material such as aluminum, steel, stainless steel, or copper. In at least one embodiment, an electronic device in contact with a cold plate is cooled by conduction. Heat from an electronic device may conduct from a device to an attached cold plate. Heat may be carried away by liquid coolant flowing through a cold plate.

In at least one embodiment, first coolant is an electrically conductive coolant. In at least one embodiment, first coolant can include water, deionized water, or a refrigerant such as R-134a, R-1234YF, 515B, or any low-global warming potential (GWP) coolant or any per-and polyfluoroalkyl (PFAs)-compliant coolant. In at least one embodiment, first coolant includes a mixture of water and additives such as a water and ethylene glycol mixture or a water and propylene glycol mixture. In at least one embodiment, first coolant includes a 25% concentration of propylene glycol in deionized water. Heat from high-power computing components is carried by first coolant to first CDU 1224. In at least one embodiment, first cooling loop 1214 includes one or more supply conduits (represented by solid lines) and one or more return conduits (represented by dashed lines). In at least one embodiment, first coolant is a single-phase coolant. In at least one embodiment, first coolant is a dual-phase coolant. In at least one embodiment, first coolant may not vaporize when heated by first computing components.

In at least one embodiment, CDU 1224 includes a heat exchanger to exchange heat between first cooling loop 1214 and a second cooling loop 1232. In at least one embodiment, second cooling loop 1232 flows another coolant, such as water, from CDU 1224 to a cooling tower 1230 to exchange heat from first cooling loop 1214 with an ambient environment. In at least one embodiment, second cooling loop 1232 flows coolant from CDU 1224 to one or more chillers to exchange heat with a cold sink such as an ambient environment. In at least one embodiment, an ambient environment includes an air environment or a liquid environment. In at least one embodiment, CDU 1224 includes one or more pumps to pump first coolant and/or another coolant of second cooling loop 1232. In at least one embodiment, CDU 1224 includes a controller to control flow and/or distribution of coolant along first cooling loop 1214 and/or second cooling loop 1232. In at least one embodiment, CDU 1224 includes one or more valves to effectuate such control. In at least one embodiment, second cooling loop 1232 may be referred to as a “primary” cooling loop, while first cooling loop 1214 may be referred to as a “secondary” cooling loop.

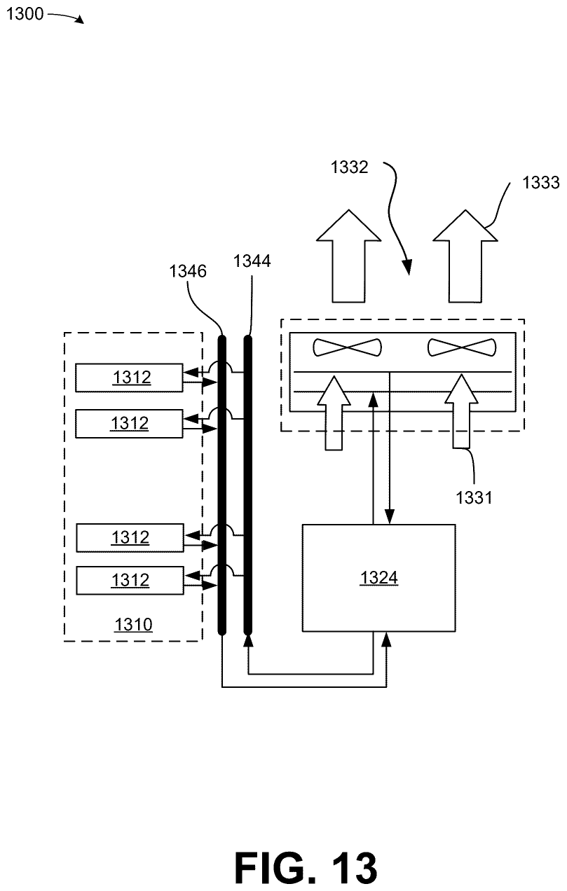

FIG. 13 illustrates a schematic diagram of a datacenter cooling system 1300, according to at least some embodiments. Features illustrated in FIG. 13 having similar numbering to features shown in FIG. 12 may have similar functions. In at least one embodiment, system 1300 includes multiple servers 1312 disposed in a datacenter rack 1310. In at least one embodiment, servers 1312 are a part of a datacenter having multiple racks 1310, each rack supporting multiple servers 1312. Although only one rack 1310 is shown in FIG. 13, system 1300 can provide cooling for servers 1312 in multiple racks 1310.

In at least one embodiment, first coolant is flowed along one or more flow paths of one or more first cooling loops from CDU 1324 to servers 1312. In at least one embodiment, first coolant is flowed through one or more manifolds. In at least one embodiment, a supply manifold 1344 is supplied with first coolant from CDU 1324. In at least one embodiment, supply manifold 1344 may distribute first coolant to multiple servers 1312 supported in rack 1310. In at least one embodiment, first coolant may flow from supply manifold 1344 into servers 1312 to cool high-power computing component(s) of servers 1312. First coolant may flow to one or more cold plates in servers 1312 and/or to one or more cooling devices for cooling bottom side computing components via one or more heat-conducting components as described herein.

In at least one embodiment, high-power computing components within servers 1312 may each be coupled to one or more cold plates to receive first coolant. In at least one embodiment, one or more cold plates may transfer heat from a high-power computing component to first coolant. In at least one embodiment, first coolant carries heat away from high-power computing components of servers 1312. In at least one embodiment, a return manifold 1346 collects heated first coolant output from each of servers 1312. In at least one embodiment, first coolant flows from return manifold 1346 to CDU 1324, where first coolant is cooled by chilled water or other coolant flowing between chiller 1332 and CDU 1324. In at least one embodiment, heat may be exchanged between first coolant and cooled water or other coolant in a liquid-to-liquid heat exchanger within CDU 1324. In at least one embodiment, cooled first coolant is again flowed from CDU 1324 to servers 1312 via supply manifold 1344.

In at least one embodiment, water or another coolant flows between chiller 1332 and CDU 1324 via a second cooling loop. In at least one embodiment, cool air 1331 is drawn into chiller 1332 by one or more fans. In at least one embodiment, water, or another coolant, carrying heat transferred from first cooling loop (e.g., via heat exchangers in CDU 1324), is cooled by cool air 1331. In at least one embodiment, heat from water or another coolant is transferred to air, and heated air 1333 is forced out of chiller 1332 (by one or more fans). In at least one embodiment, water or another coolant is therefore cooled by air. In at least one embodiment, cooled water flows back to CDU 1324 along a flow path of a second cooling loop.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit the disclosure to a specific form or forms disclosed, but on the contrary, the intention is to cover all modifications, alternative constructions, and equivalents falling within the spirit and scope of the disclosure, as defined in appended claims.

Use of terms “a” and “an” and “the” and similar referents in the context of describing disclosed embodiments (especially in the context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitations of ranges of values herein are merely intended to serve as a shorthand method of referring individually to each separate value falling within the range, unless otherwise indicated herein, and each separate value is incorporated into the specification as if it were individually recited herein. In at least one embodiment, the use of the term “set” (e.g., “a set of items”) or “subset” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but subset and corresponding set may be equal.

Conjunctive language, such as phrases of the form “at least one of A, B, and C,” or “at least one of A, B and C,” unless specifically stated otherwise or otherwise clearly contradicted by context, is otherwise understood with the context as used in general to present that an item, term, etc., may be either A or B or C, or any nonempty subset of the set of A and B and C. For instance, in an illustrative example of a set having three members, conjunctive phrases “at least one of A, B, and C” and “at least one of A, B and C” refer to any of the following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, the term “plurality” indicates a state of being plural (e.g., “a plurality of items” indicates multiple items). In at least one embodiment, the number of items in a plurality is at least two, but can be more when so indicated either explicitly or by context. Further, unless stated otherwise or otherwise clear from context, the phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in the form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause a computer system to perform operations described herein. In at least one embodiment, a set of non-transitory computer-readable storage media comprises multiple non-transitory computer-readable storage media and one or more of individual non-transitory storage media of multiple non-transitory computer-readable storage media lack all of the code while multiple non-transitory computer-readable storage media collectively store all of the code. In at least one embodiment, executable instructions are executed such that different instructions are executed by different processors.

Accordingly, in at least one embodiment, computer systems are configured to implement one or more services that singly or collectively perform operations of processes described herein and such computer systems are configured with applicable hardware and/or software that enable the performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

In description and claims, terms “coupled” and “connected,” along with their derivatives, may be used. It should be understood that these terms may not be intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, the term “processor” may refer to any device or portion of a device that processes electronic data from registers and/or memory and transform that electronic data into other electronic data that may be stored in registers and/or memory. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously, or intermittently. In at least one embodiment, terms “system” and “method” are used herein interchangeably insofar as the system may embody one or more methods and methods may be considered a system.

In the present document, references may be made to obtaining, acquiring, receiving, or inputting analog or digital data into a subsystem, computer system, or computer-implemented machine. In at least one embodiment, the process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface or inter-process communication mechanism.

Although descriptions herein set forth example embodiments of described techniques, other architectures may be used to implement described functionality, and are intended to be within the scope of this disclosure. Furthermore, although specific distributions of responsibilities may be defined above for purposes of description, various functions and responsibilities might be distributed and divided in different ways, depending on circumstances.

Furthermore, although the subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A system, comprising:
one or more computing components disposed on a first side of a circuit board within a server chassis;
a cooling device disposed at least partially on a second side of the circuit board opposite the first side of the circuit board; and
a heat-conducting component configured to transport heat away from a first computing component of the one or more computing components to the cooling device, wherein the heat-conducting component comprises:
a main body coupled to the one or more computing components, wherein the main body is approximately parallel to the circuit board; and
a heat-dissipation feature extending from the main body, wherein the heat-dissipation feature extends from the first side of the circuit board to the second side of the circuit board and is coupled with the cooling device.

2. The system of claim 1, further comprising:
a thermal interface attached to the cooling device, the thermal interface comprising:
a thermal interface pad disposed between the heat-dissipation feature of the heat-conducting component and the cooling device; and
a copper layer disposed on the thermal interface pad, wherein the copper layer is configured to provide a protective buffer between the thermal interface pad and the heat-dissipation feature of the heat-conducting component.

3. The system of claim 2, wherein the copper layer comprises a plurality of slits, and wherein the thermal interface pad is to squeeze at least partially into the plurality of slits responsive to a compressive force exerted on the thermal interface pad responsive to insertion of the heat-dissipation feature into the thermal interface.

4. The system of claim 2, wherein the thermal interface is configured to be reusable for a plurality of mating cycles.

5. The system of claim 2, wherein the thermal interface pad is wrapped on top of the copper layer between the copper layer and an inner surface of the cooling device, and wherein the thermal interface pad and copper layer form a compression fit within the cooling device.

6. The system of claim 1, wherein the heat-conducting component comprises a vapor chamber or a solid body of heat-conducting material.

7. The system of claim 6, wherein the heat-conducting component comprises the vapor chamber, wherein the vapor chamber forms a closed-loop fluid cycle to transport heat away from the first computing component to the cooling device, and wherein the heat-dissipation feature forms a hollow cavity of the vapor chamber.

8. The system of claim 6, wherein the heat-conducting component comprises the solid body of heat-conducting material, and wherein the heat-conducting material has a heat conductivity between approximately 300 W/(m*K) and approximately 5,000 W/(m*K).

9. The system of claim 1, wherein the heat-dissipation feature of the heat-conducting component is substantially orthogonal to the main body of the heat-conducting component and is either (i) an integrated feature of the main body, or (ii) coupled with the main body.

10. The system of claim 1, wherein the heat-dissipation feature increases a surface area of the heat-conducting component for dissipating heat by between approximately 5× and approximately 10× of a surface area of the heat-conducting component for dissipating heat absent the heat-dissipation feature.

11. The system of claim 1, wherein the main body of the heat-conducting component has a thickness between approximately one millimeter and approximately seven millimeters.

12. The system of claim 1, wherein the first side is a bottom side of the circuit board and wherein the second side is a top side of the circuit board, and wherein the heat-conducting component is configured to transport the heat from the first computing component on the bottom side of the circuit board to the top side of the circuit board.

13. The system of claim 1, wherein the main body of the heat-conducting component is disposed substantially between the one or more computing components and a bottom of the server chassis, and wherein the cooling device is disposed adjacent to a side wall of the server chassis.

14. The system of claim 1, wherein the cooling device is configured to receive a flow of liquid coolant, and wherein the heat from the first computing component is provided to the flow of liquid coolant by the heat-conducting component and cooling device.

15. A heat-conducting component, comprising:
a main body configured to couple to a computing component on a first side of a circuit board, wherein the main body is to be approximately parallel to the circuit board; and
a heat-dissipation feature extending from the main body, wherein the heat-dissipation feature extends from the first side of the circuit board to a second side of the circuit board opposite the first side, wherein the heat-dissipation feature is configured to couple with a cooling device, and wherein the heat-conducting component is configured to transport heat away from the computing component to the cooling device.

16. The heat-conducting component of claim 15, wherein the heat-conducting component comprises a vapor chamber, wherein the vapor chamber forms a closed-loop fluid cycle to transport heat away from the computing component to the cooling device, and wherein the heat-dissipation feature forms a hollow cavity of the vapor chamber.

17. The heat-conducting component of claim 15, wherein the heat-conducting component has a heat conductivity between approximately 300 W/(m*K) and approximately 5,000 W/(m*K).

18. The heat-conducting component of claim 15, wherein the main body has a thickness between approximately one millimeter and approximately seven millimeters.

19. A vapor chamber, comprising:
a main body configured to couple to a computing component on a first side of a circuit board; and
a heat-dissipation feature extending from the main body, wherein the heat-dissipation feature extends from the first side of the circuit board to a second side of the circuit board opposite the first side, wherein the heat-dissipation feature is configured to couple with a cooling device, and wherein the vapor chamber forms a closed-loop fluid cycle configured to transport heat away from the computing component to the cooling device.

20. The vapor chamber of claim 19, wherein the main body has a thickness between approximately one millimeter and approximately seven millimeters.

21. A datacenter, comprising:
one or more computing components disposed on a first side of a circuit board within a server chassis;
a cooling device disposed at least partially on a second side of the circuit board opposite the first side of the circuit board; and
a heat-conducting component configured to transport heat away from a first computing component of the one or more computing components to the cooling device, wherein the heat-conducting component comprises:
a main body coupled to the one or more computing components, wherein the main body is approximately parallel to the circuit board; and
a heat-dissipation feature extending from the main body, wherein the heat-dissipation feature extends from the first side of the circuit board to the second side of the circuit board and is coupled with the cooling device.

22. The datacenter of claim 21, further comprising:
a thermal interface attached to the cooling device, the thermal interface comprising:
a thermal interface pad disposed between the heat-dissipation feature of the heat-conducting component and the cooling device; and
a copper layer disposed on the thermal interface pad, wherein the copper layer is configured to provide a protective buffer between the thermal interface pad and the heat-dissipation feature of the heat-conducting component.

23. The datacenter of claim 21, wherein the heat-conducting component comprises a vapor chamber, wherein the vapor chamber forms a closed-loop fluid cycle to transport heat away from the computing component to the cooling device, and wherein the heat-dissipation feature forms a hollow cavity of the vapor chamber.

24. The datacenter of claim 21, wherein the heat-conducting component has a heat conductivity between approximately 300 W/(m*K) and approximately 5,000 W/(m*K).

25. The datacenter of claim 21, wherein the main body has a thickness between approximately one millimeter and approximately seven millimeters.
